(19) United States
(12) Patent Application Publication
(10) Pub. No.: US 2026/0314507 A1
(43) Pub. Date: Oct. 8, 2026

(54) SEMICONDUCTOR DEVICE, SEMICONDUCTOR MODULE, AND VEHICLE

(71) Applicant: ROHM CO., LTD., Kyoto-shi (JP)

(72) Inventor: Daiki IKEDA, Kyoto-shi (JP)

(21) Appl. No.: 19/678,312

(22) Filed: May 15, 2026

Related U.S. Application Data
(63) Continuation of application No. PCT/JP2024/039393, filed on Nov. 6, 2024.

(30) Foreign Application Priority Data
Nov. 22, 2023 (JP) 2023-198560

(51) Int. Cl. H10W 90/00; H10D 80/20; H10W 40/20; H10W 40/22; H10W 70/60; H10W 70/65; H10W 70/652; H10W 70/654; H10W 74/10; H10W 90/10

(52) U.S. Cl. CPC H10W 90/764; H10D 80/251; H10W 40/226; H10W 40/235; H10W 70/611; H10W 70/652; H10W 70/654; H10W 70/658; H10W 74/114; H10W 74/127; H10W 90/10; H10W 90/734; H10W 90/754; H10W 90/763

(57) ABSTRACT

The semiconductor device is configured to reduce positional displacement of the device relative to a heat sink. The semiconductor device includes a first conductive layer, a first semiconductor element, a target member and a sealing resin. The first semiconductor element is electrically connected to the first conductive layer. The sealing resin covers the first conductive layer, the first semiconductor element and a part of the target member. The sealing resin includes a first surface facing a first direction, and a first opening open to the first surface. The target member includes a first engaging portion exposed from the first opening.

### TECHNICAL FIELD

The present disclosure relates to a semiconductor device, a semiconductor module in which the semiconductor device is mounted on a heat sink, and a vehicle in which the semiconductor device is installed.

### BACKGROUND ART

Conventionally, semiconductor devices on which semiconductor elements having a switching function (MOSFETs and IGBTs) are mounted have been widely known, and are mainly used for power conversion. WO-2023/047890-A1 discloses an example of such a semiconductor device. The semiconductor device disclosed in the document includes a sealing resin covering the semiconductor elements, a heat sink, and an attachment member. The attachment member is a plate spring. The semiconductor device is attached to the heat sink through the plate spring. The sealing resin is pressed against the attachment member.

Apart from the semiconductor device disclosed in WO-2023/047890-A1, there are cases in which a base material of a semiconductor device is bonded to a heat sink via a bonding layer. The base material supports a semiconductor element and is exposed from the sealing resin. For example, the bonding layer is a sintered body of metal particles, and is formed by sintering. In such a case, the base material may be displaced with respect to the heat sink. If the amount of displacement of the base material with respect to the heat sink is larger, installation of a wiring board or the like on the semiconductor device may become difficult.

### BRIEF DESCRIPTION OF THE DRAWINGS

FIG. 1 is a perspective view of a semiconductor device according to a first embodiment of the present disclosure.

FIG. 2 is a plan view of the semiconductor device shown in FIG. 1.

FIG. 3 is a plan view corresponding to FIG. 2, in which the sealing resin is shown transparently.

FIG. 4 is a partially enlarged view of FIG. 3.

FIG. 5 is a plan view corresponding to FIG. 2, in which the sealing resin and the second conductive member are omitted.

FIG. 6 is a right-side view of the semiconductor device shown in FIG. 1.

FIG. 7 is a left-side view of the semiconductor device shown in FIG. 1.

FIG. 8 is a front view of the semiconductor device shown in FIG. 1.

FIG. 9 is a back view of the semiconductor device shown in FIG. 1.

FIG. 10 is a bottom view of the semiconductor device shown in FIG. 1.

FIG. 11 is a sectional view taken along line XI-XI in FIG. 3.

FIG. 12 is a sectional view taken along line XII-XII in FIG. 3.

FIG. 13 is a partially enlarged view of the first semiconductor element and its peripheral part shown in FIG. 12.

FIG. 14 is a partially enlarged view of the second semiconductor element and its peripheral part shown in FIG. 12.

FIG. 15 is a sectional view taken along line XV-XV in FIG. 3.

FIG. 16 is a sectional view taken along line XVI-XVI in FIG. 3.

FIG. 17 is a partially enlarged view of FIG. 3.

FIG. 18 is a sectional view taken along line XVIII-XVIII in FIG. 17.

FIG. 19 is a sectional view taken along line XIX-XIX in FIG. 17.

FIG. 20 is a plan view of a semiconductor module according to the first embodiment of the present disclosure.

FIG. 21 is a partially enlarged view of FIG. 20.

FIG. 22 is a sectional view taken along line XXII-XXII in FIG. 21.

FIG. 23 is a schematic view of a vehicle on which the semiconductor device shown in FIG. 1 is installed.

FIG. 24 is a partially enlarged plan view of a semiconductor device according to a second embodiment of the present disclosure, corresponding to FIG. 17.

FIG. 25 is a partially enlarged plan view of a semiconductor module according to the second embodiment of the present disclosure, corresponding to FIG. 21.

FIG. 26 is a partially enlarged plan view of a semiconductor device according to a third embodiment of the present disclosure, corresponding to FIG. 17.

FIG. 27 is a sectional view taken along line XXVII-XXVII in FIG. 26.

FIG. 28 is a partially enlarged plan view of a semiconductor device according to a fourth embodiment of the present disclosure, corresponding to FIG. 17.

FIG. 29 is a sectional view taken along line XXIX-XXIX in FIG. 28.

FIG. 30 is a partially enlarged plan view of a semiconductor device according to a fifth embodiment of the present disclosure, corresponding to FIG. 17.

FIG. 31 is a sectional view taken along line XXXI-XXXI in FIG. 30.

FIG. 32 is a partially enlarged plan view of a semiconductor device according to a sixth embodiment of the present disclosure, corresponding to FIG. 17.

FIG. 33 is a sectional view taken along line XXXIII-XXXIII in FIG. 32.

FIG. 34 is a partially enlarged plan view of a semiconductor device according to a seventh embodiment of the present disclosure, corresponding to FIG. 17.

FIG. 35 is a sectional view taken along line XXXV-XXXV in FIG. 34.

FIG. 36 is a partially enlarged sectional view of a semiconductor module according to the third embodiment of the present disclosure.

### DETAILED DESCRIPTION

Details of the present disclosure will be described below with reference to the accompanying drawings.

### First Embodiment:

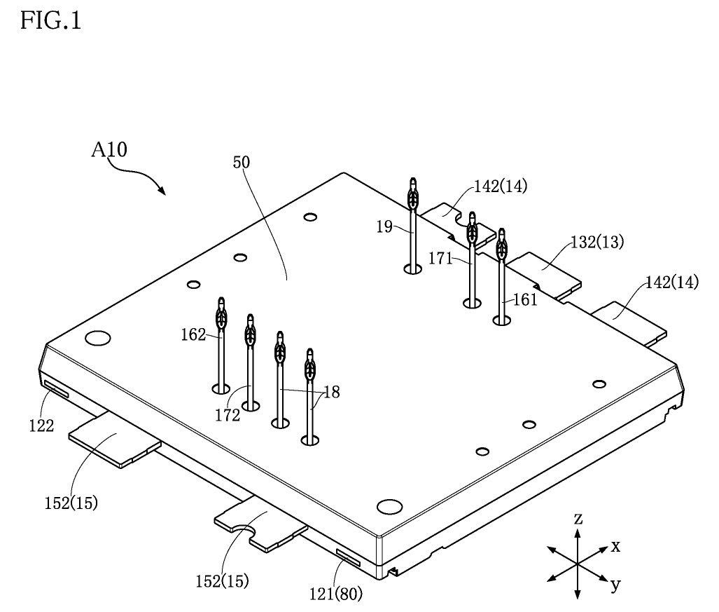

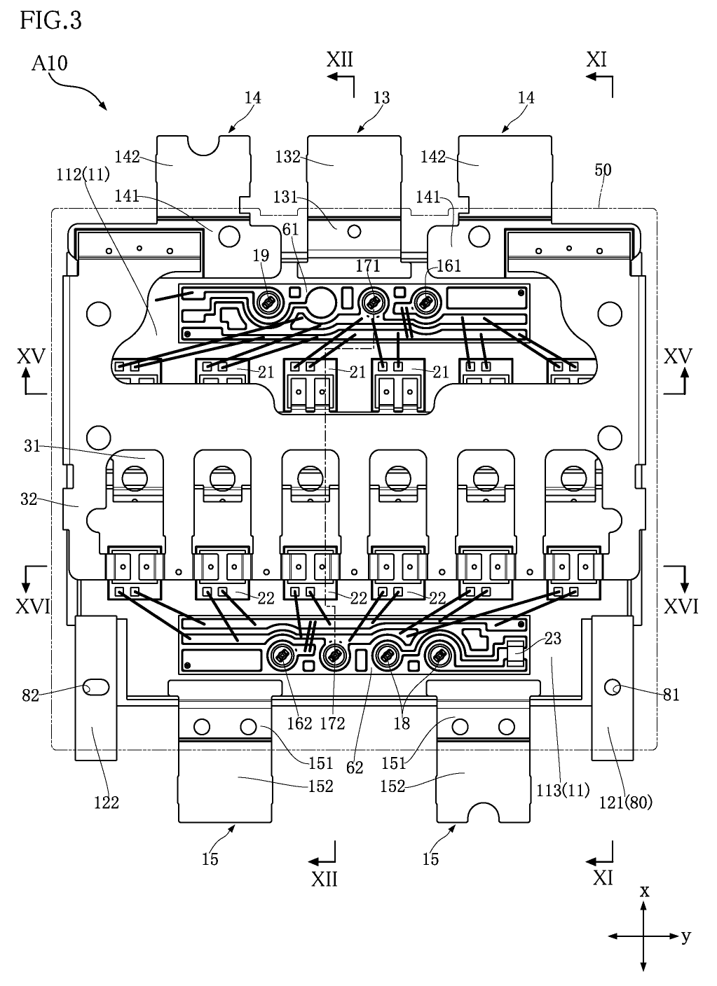

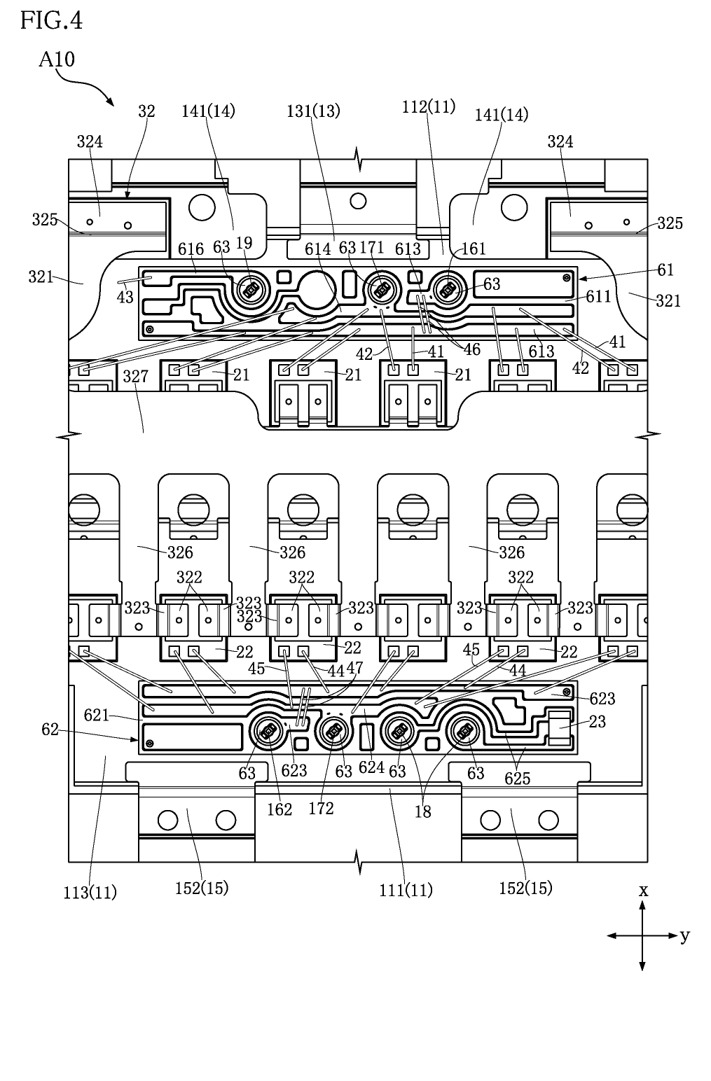

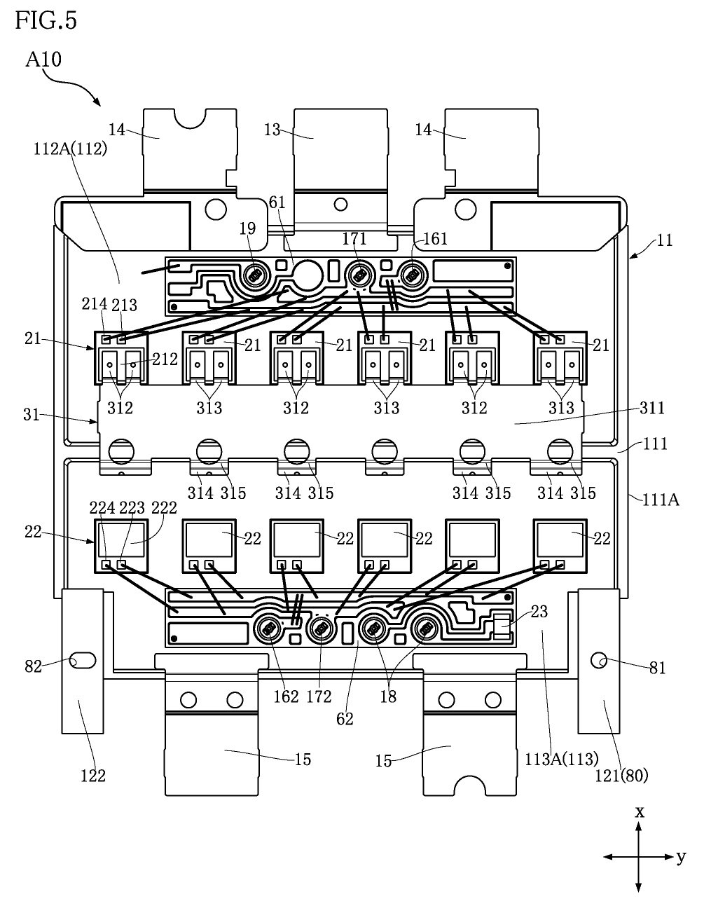

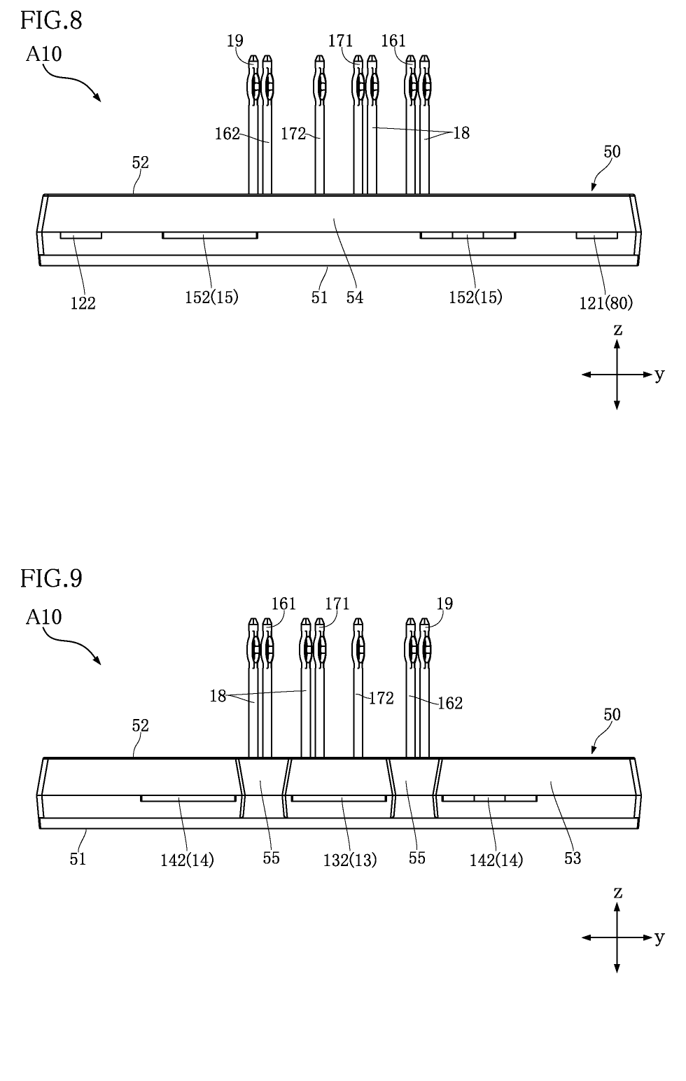

A semiconductor device A10 according to a first embodiment of the present disclosure will be described below with reference to FIGS. 1-19. The semiconductor device A10 includes a base material 11, a first dummy terminal 121, a second dummy terminal 122, a first terminal 13, two second terminals 14, two third terminals 15, a plurality of first semiconductor elements 21, a plurality of second semiconductor elements 22, a first conductive member 31, a second conductive member 32, and a sealing resin 50. The semiconductor device A10 further includes a first signal terminal 161, a second signal terminal 162, a third signal terminal 171, a fourth signal terminal 172, two fifth signal terminals 18, a sixth signal terminal 19, a thermistor 23, a first wiring 61, and a second wiring 62. For convenience of understanding, in FIGS. 3 and 4, the sealing resin 50 is shown transparently. In FIG. 3, the transparent sealing resin 50 is indicated by imaginary lines (two-dot chain lines). In FIG. 5, the sealing resin 50 and the second conductive member 32 are omitted for convenience of understanding.

In the description of the semiconductor device A10, for convenience, a normal direction of a first surface 51 of the sealing resin 50, which will be described later, is referred to as a “first direction z”. A direction orthogonal to the first direction z is referred to as a “second direction x”. A direction orthogonal to the first direction z and the second direction x is referred to as a “third direction y”.

The semiconductor device A10 converts DC power input to the first terminal 13 and the two second terminals 14 into AC power through the first semiconductor elements 21 and the second semiconductor elements 22. The converted AC power is output from each of the two third terminals 15 to a power supply target such as a motor.

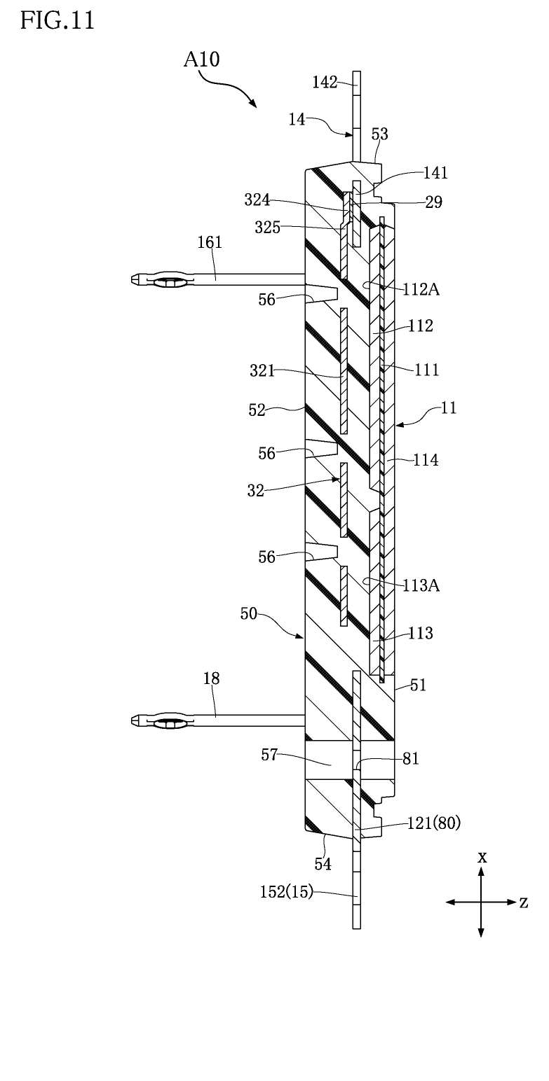

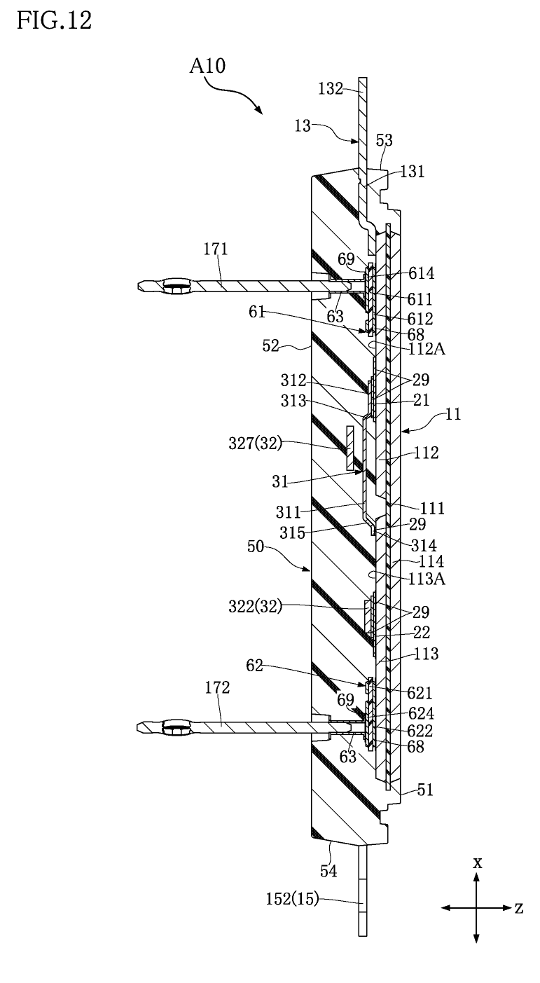

As shown in FIGS. 12, 15 and 16, the base material 11 is located on a first side in the first direction z of each of the first semiconductor elements 21 and the second semiconductor elements 22. In the semiconductor device A10, the base material 11 is composed of, for example, a substrate formed by active metal brazing (AMB). As shown in FIGS. 11 and 12, the base material 11 includes an insulating layer 111, a first conductive layer 112, a second conductive layer 113, and a heat dissipation layer 114. The base material 11 is covered with the sealing resin 50 except for a part of the heat dissipation layer 114.

As shown in FIGS. 11 and 12, the insulating layer 111 includes a portion interposed, in the first direction z, between the heat dissipation layer 114 and the first conductive layer 112 or the second conductive layer 113. The insulating layer 111 is made of a material having relatively high thermal conductivity. The insulating layer 111 is made of ceramics containing aluminum nitride (AlN), for example. The insulating layer 111 has a dimension in the first direction z that is smaller than a dimension in the first direction z of each of the first conductive layer 112 and the second conductive layer 113.

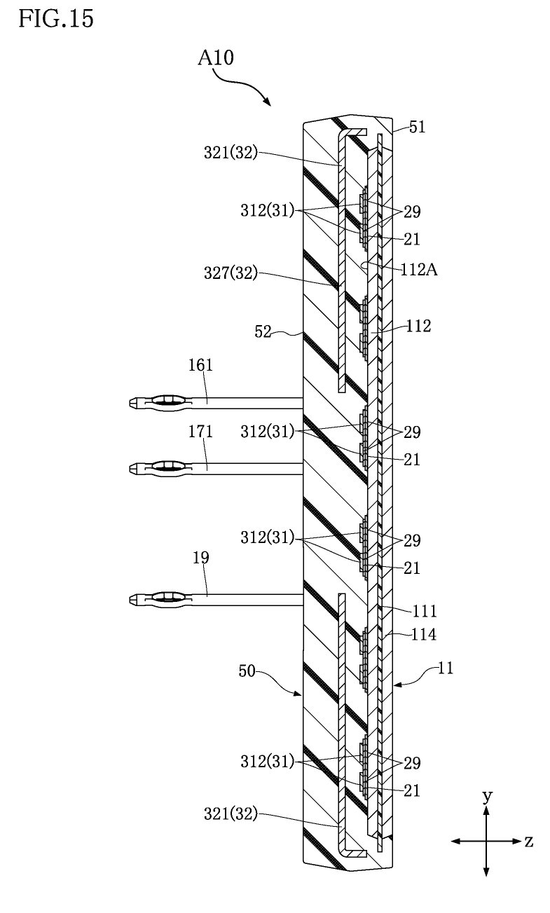

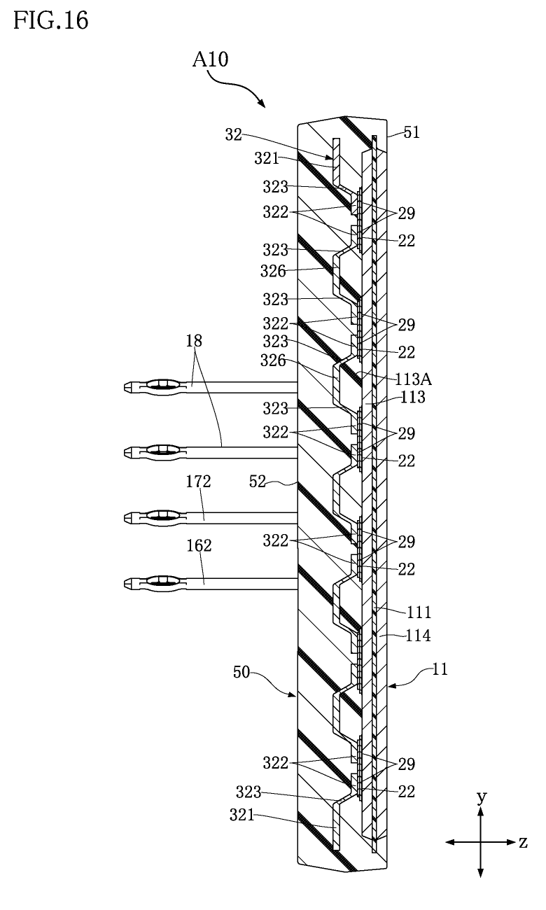

As shown in FIGS. 12, 15, and 16, the first conductive layer 112 is located between the insulating layer 111 and the first semiconductor elements 21 in the first direction z, and the second conductive layer 113 is located between the insulating layer 111 and the second semiconductor elements 22 in the first direction z. The first conductive layer 112 and the second conductive layer 113 are bonded to the insulating layer 111. The first conductive layer 112 and the second conductive layer 113 contain copper (Cu). The first conductive layer 112 and the second conductive layer 113 are spaced apart from each other in the second direction x. As shown in FIGS. 12 and 15, the first conductive layer 112 includes a first obverse surface 112A facing the first direction z. The first obverse surface 112A faces the first semiconductor elements 21. As shown in FIGS. 12 and 16, the second conductive layer 113 includes a second obverse surface 113A facing the same side as the first obverse surface 112A in the first direction z. The second obverse surface 113A faces the second semiconductor elements 22. As viewed in the first direction z, each of the first conductive layer 112 and the second conductive layer 113 is located inward of a peripheral edge 111A of the insulating layer 111.

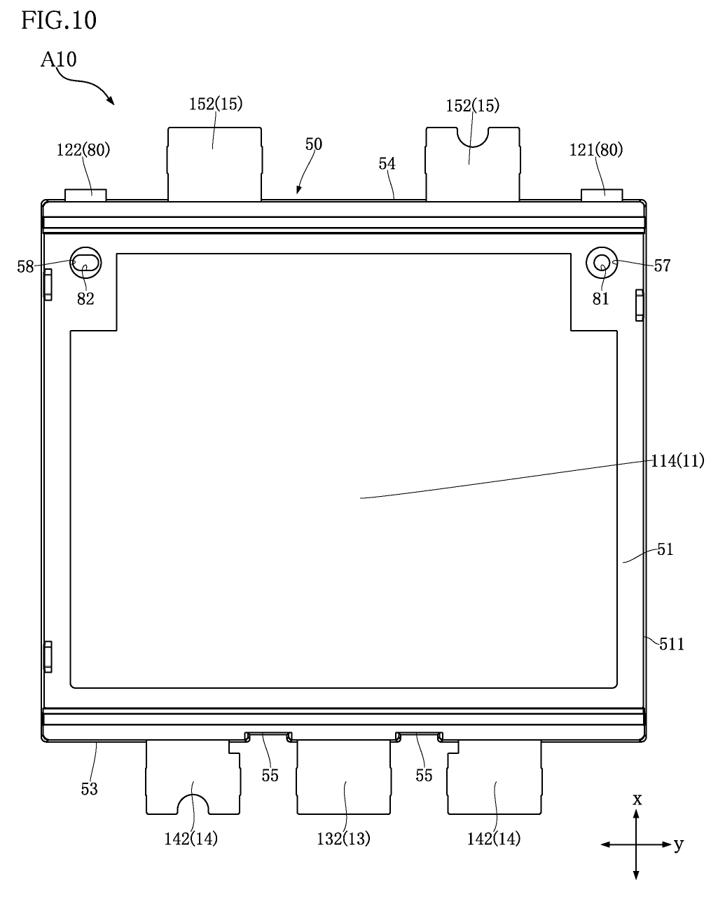

As shown in FIGS. 11 and 12, the heat dissipation layer 114 is located opposite to the first conductive layer 112 and the second conductive layer 113 with respect to the insulating layer 111 in the first direction z. As shown in FIG. 10, the heat dissipation layer 114 is exposed from the sealing resin 50. The heat dissipation layer 114 contains copper. The heat dissipation layer 114 has a dimension in the first direction z that is larger than a dimension in the first direction z of the insulating layer 111. As viewed in the first direction z, the heat dissipation layer 114 is located inward of the peripheral edge 111A of the insulating layer 111.

As shown in FIGS. 5 and 15, the first semiconductor elements 21 are bonded to the first obverse surface 112A of the first conductive layer 112. The first semiconductor elements 21 are arranged along the third direction y. As shown in FIGS. 5 and 16, the second semiconductor elements 22 are bonded to the second obverse surface 113A of the second conductive layer 113. The second semiconductor elements 22 are arranged along the third direction y. The first semiconductor elements 21 and the second semiconductor elements 22 are, for example, MOSFETs (Metal-Oxide-Semiconductor Field-Effect Transistors). Alternatively, the first semiconductor elements 21 and the second semiconductor elements 22 may be switching elements such as IGBTs (Insulated Gate Bipolar Transistors). Further, the first semiconductor elements 21 may include switching elements and freewheeling diodes individually connected in parallel to the switching elements. Similarly, the second semiconductor elements 22 may include switching elements and freewheeling diodes individually connected in parallel to the switching elements. Each freewheeling diode is, for example, a Schottky barrier diode. In the description of the semiconductor device A10, the first semiconductor elements 21 and the second semiconductor elements 22 are assumed to be n-channel type MOSFETs of a vertical structure. Each of the first semiconductor elements 21 and the second semiconductor elements 22 includes a compound semiconductor substrate. The compound semiconductor substrate contains silicon carbide (SiC).

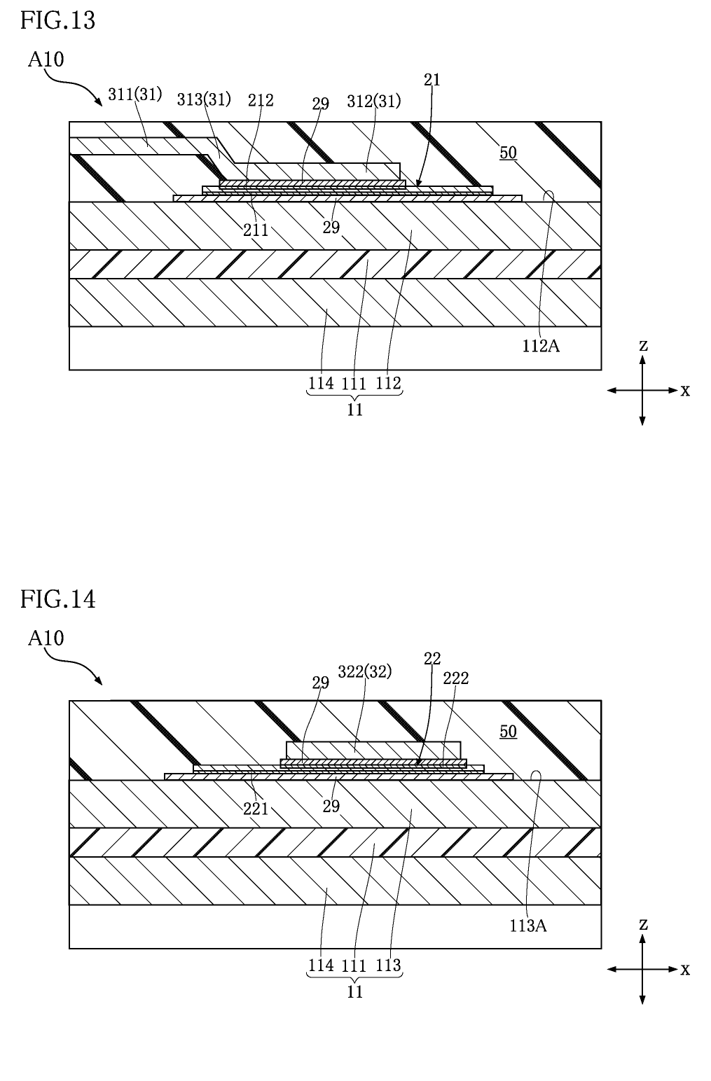

As shown in FIGS. 5 and 13, each of the first semiconductor elements 21 includes a first electrode 211, a second electrode 212, a first gate electrode 213, and a first detection electrode 214.

As shown in FIG. 13, each first electrode 211 faces the first obverse surface 112A of the first conductive layer 112. A current corresponding to electric power before conversion in each first semiconductor element 21 flows through the first electrode 211. That is, each first electrode 211 corresponds to a drain electrode of each first semiconductor element 21. Each first electrode 211 is conductively bonded to the first obverse surface 112A through a conductive bonding layer 29. As a result, the first electrode 211 of each first semiconductor element 21 is electrically connected to the first conductive layer 112. Each conductive bonding layer 29 is a sintered body of metal particles including silver (Ag) or the like. Alternatively, the conductive bonding layer 29 may be solder.

As shown in FIG. 13, each second electrode 212 is located on a side opposite to the first obverse surface 112A of the first conductive layer 112 in the first direction z. Hence, the first electrodes 211 and the second electrodes 212 are located opposite to each other in the first direction z. A current corresponding to electric power after conversion in each first semiconductor element 21 flows through the second electrode 212. That is, each second electrode 212 corresponds to a source electrode of each first semiconductor element 21.

As shown in FIG. 5, each first gate electrode 213 is located on the same side as each second electrode 212 in the first direction z. Each first gate electrode 213 receives a gate voltage for driving the corresponding first semiconductor element 21. As shown in FIG. 5, as viewed in the first direction z, each first gate electrode 213 has an area that is smaller than an area of the corresponding second electrode 212.

As shown in FIG. 5, each first detection electrode 214 is located on the same side as each second electrode 212 and each first gate electrode 213 in the first direction z. Each first detection electrode 214 is located next to the corresponding first gate electrode 213 in the third direction y. Each first detection electrode 214 receives a voltage equivalent to that applied to the corresponding second electrode 212. As viewed in the first direction z, each first detection electrode 214 has an area that is substantially equal to an area of the corresponding first gate electrode 213.

As shown in FIGS. 5 and 14, each of the second semiconductor elements 22 includes a third electrode 221, a fourth electrode 222, a second gate electrode 223, and a second detection electrode 224.

As shown in FIG. 14, each third electrode 221 faces the second obverse surface 113A of the second conductive layer 113. A current corresponding to electric power before conversion in each second semiconductor element 22 flows through the third electrode 221. That is, each third electrode 221 corresponds to a drain electrode of each second semiconductor element 22. Each third electrode 221 is conductively bonded to the second obverse surface 113A through a conductive bonding layer 29. Hence, the third electrode 221 of each of the second semiconductor elements 22 is electrically connected to the second conductive layer 113.

As shown in FIG. 14, each fourth electrode 222 is located on a side opposite to the second obverse surface 113A of the second conductive layer 113 in the first direction z. Hence, the third electrode 221 and the fourth electrode 222 are located opposite to each other in the first direction z. A current corresponding to electric power after conversion in each second semiconductor element 22 flows through the fourth electrode 222. That is, each fourth electrode 222 corresponds to a source electrode of each second semiconductor element 22.

As shown in FIG. 5, each second gate electrode 223 is located on the same side as each fourth electrode 222 in the first direction z. Each second gate electrode 223 receives a gate voltage for driving the corresponding second semiconductor element 22. As shown in FIG. 5, as viewed in the first direction z, each second gate electrode 223 has an area that is smaller than an area of the corresponding fourth electrode 222.

As shown in FIG. 5, each second detection electrode 224 is located on the same side as each fourth electrode 222 and each second gate electrode 223 in the first direction z. The second detection electrode 224 is located on both sides of the second gate electrode 223 in the third direction y. Each second detection electrode 224 receives a voltage equivalent to that applied to the fourth electrode 222. As viewed in the first direction z, each second detection electrode 224 has an area that is substantially equal to an area of the corresponding second gate electrode 223.

As shown in FIGS. 5 and 12, the first terminal 13 is located on a side opposite to the second conductive layer 113 with respect to the first conductive layer 112 in the second direction x. The first terminal 13 is conductively bonded to the first conductive layer 112. Hence, the first terminal 13 is electrically connected to the first electrode 211 of each first semiconductor element 21 through the first conductive layer 112. The first terminal 13 is a P terminal (positive electrode) to which DC power to be converted is input. The first terminal 13 extends in the second direction x from the first conductive layer 112. The first terminal 13 includes a covered portion 131 and an exposed portion 132. As shown in FIG. 12, the covered portion 131 is conductively bonded to the first conductive layer 112, and is covered with the sealing resin 50. The exposed portion 132 extends in the second direction x from the covered portion 131, and projects from the sealing resin 50.

As shown in FIGS. 5 and 11, each of the two second terminals 14 is located on the same side as the first terminal 13 with respect to the first conductive layer 112 and the second conductive layer 113 in the second direction x, and is spaced apart from the first conductive layer 112 and the second conductive layer 113. Each of the two second terminals 14 is electrically connected to the fourth electrode 222 of each of the second semiconductor elements 22. The two second terminals 14 are N terminals (negative electrodes) to which DC power to be converted is input. The two second terminals 14 are spaced apart from each other in the third direction y. The first terminal 13 is located between the two second terminals 14 in the third direction y. Each of the two second terminals 14 includes a covered portion 141 and an exposed portion 142. As shown in FIG. 11, each covered portion 141 is spaced apart from the first conductive layer 112 and is covered with the sealing resin 50. Each exposed portion 142 extends in the second direction x from the corresponding covered portion 141 and projects from the sealing resin 50.

As shown in FIG. 5, each of the two third terminals 15 is located on a side opposite to the first conductive layer 112 with respect to the second conductive layer 113 in the second direction x. Each of the two third terminals 15 is conductively bonded to the second conductive layer 113. Hence, each of the two third terminals 15 is electrically connected to the third electrode 221 of each second semiconductor element 22 through the second conductive layer 113. AC power converted by the first semiconductor elements 21 and the second semiconductor elements 22 is output from each of the two third terminals 15. In the semiconductor device A10, the two third terminals 15 are spaced apart from each other in the third direction y. As shown in FIG. 3, each of the two third terminals 15 includes a covered portion 151 and an exposed portion 152. Each covered portion 151 is conductively bonded to the second conductive layer 113 and is covered with the sealing resin 50. Each exposed portion 152 extends in the second direction x from the corresponding covered portion 151 and projects from the sealing resin 50.

As shown in FIG. 12, the first wiring 61 is bonded to the first obverse surface 112A of the first conductive layer 112. The first wiring 61 is located on a side opposite to the second semiconductor elements 22 with respect to the first semiconductor elements 21 in the second direction x. The first wiring 61 is electrically connected to the first semiconductor elements 21 and the first conductive layer 112. As shown in FIGS. 4 and 12, the first wiring 61 includes a first mounting layer 611, a first metal layer 612, two first gate wiring layers 613, a first detection wiring layer 614, and a second detection wiring layer 616.

As shown in FIG. 4, the first mounting layer 611 carries the two first gate wiring layers 613, the first detection wiring layer 614, and the second detection wiring layer 616. The first mounting layer 611 is an insulator. The first mounting layer 611 is made of, for example, ceramics. Alternatively, the first mounting layer 611 may be made of an insulating resin sheet.

As shown in FIG. 12, the first metal layer 612 is located, in the first direction z, between the first mounting layer 611 and the first obverse surface 112A of the first conductive layer 112. The first metal layer 612 is bonded to the first mounting layer 611. The first metal layer 612 contains copper. The first metal layer 612 is bonded to the first obverse surface 112A through the first bonding layer 68. The first bonding layer 68 is, for example, solder.

As shown in FIGS. 4 and 12, the two first gate wiring layers 613 are located on a side opposite to the first metal layer 612 with respect to the first mounting layer 611. The two first gate wiring layers 613 are bonded to the first mounting layer 611. Among the two first gate wiring layers 613, a plurality of first wires 41 are conductively bonded to one first gate wiring layer 613. The first wires 41 are conductively bonded to the first gate electrodes 213 of the first semiconductor elements 21, respectively. Further, a plurality of sixth wires 46 are conductively bonded to each of the two first gate wiring layers 613. Hence, each of the two first gate wiring layers 613 is electrically connected to the first gate electrode 213 of each of the first semiconductor elements 21.

As shown in FIGS. 4 and 12, the first detection wiring layer 614 is located on a side opposite to the first metal layer 612 with respect to the first mounting layer 611. The first detection wiring layer 614 is bonded to the first mounting layer 611. A plurality of second wires 42 are conductively bonded to the first detection wiring layer 614. Further, the second wires 42 are conductively bonded to the first detection electrode 214 of the first semiconductor elements 21, respectively. Hence, the first detection wiring layer 614 is electrically connected to the first detection electrode 214 of each of the first semiconductor elements 21.

As shown in FIGS. 4 and 12, the second detection wiring layer 616 is located on a side opposite to the first metal layer 612 with respect to the first mounting layer 611. The second detection wiring layer 616 is bonded to the first mounting layer 611. A third wire 43 is conductively bonded to the second detection wiring layer 616. Further, the third wire 43 is conductively bonded to the first obverse surface 112A of the first conductive layer 112. Hence, the second detection wiring layer 616 is electrically connected to the first conductive layer 112.

As shown in FIG. 12, the second wiring 62 is bonded to the second obverse surface 113A of the second conductive layer 113. The second wiring 62 is located on a side opposite to the first semiconductor elements 21 with respect to the second semiconductor elements 22 in the second direction x. The second wiring 62 is electrically connected to the second semiconductor elements 22 and the second conductive layer 113. As shown in FIGS. 4 and 12, the second wiring 62 includes a second mounting layer 621, a second metal layer 622, two second gate wiring layers 623, a third detection wiring layer 624, and two temperature detection wiring layers 625.

As shown in FIG. 4, the second mounting layer 621 carries the two second gate wiring layers 623, the third detection wiring layer 624, and the two temperature detection wiring layers 625. The second mounting layer 621 is an insulator. The second mounting layer 621 is made of, for example, ceramics. Alternatively, the second mounting layer 621 may be made of an insulating resin sheet.

As shown in FIG. 12, the second metal layer 622 is located, in the first direction z, between the second mounting layer 621 and the second obverse surface 113A of the second conductive layer 113. The second metal layer 622 is bonded to the second mounting layer 621. The second metal layer 622 contains copper. The second metal layer 622 is bonded to the second obverse surface 113A through the first bonding layer 68.

As shown in FIGS. 4 and 12, the two second gate wiring layers 623 are located on a side opposite to the second metal layer 622 with respect to the second mounting layer 621. The two second gate wiring layers 623 are bonded to the second mounting layer 621. Among the two second gate wiring layers 623, a plurality of fourth wires 44 are conductively bonded to one second gate wiring layer 623. The fourth wires 44 are conductively bonded to the second gate electrodes 223 of the second semiconductor elements 22, respectively. Further, a plurality of seventh wires 47 are conductively bonded to each of the two second gate wiring layers 623. Hence, each of the two second gate wiring layers 623 is electrically connected to the second gate electrode 223 of each of the second semiconductor elements 22.

As shown in FIGS. 4 and 12, the third detection wiring layer 624 is located on a side opposite to the second metal layer 622 with respect to the second mounting layer 621. The third detection wiring layer 624 is bonded to the second mounting layer 621. A plurality of fifth wires 45 are conductively bonded to the third detection wiring layer 624. Further, the fifth wires 45 are conductively bonded to the second detection electrodes 224 of the second semiconductor elements 22, respectively. Hence, the third detection wiring layer 624 is electrically connected to the second detection electrode 224 of each of the second semiconductor elements 22.

As shown in FIGS. 4 and 12, the two temperature detection wiring layers 625 are located on a side opposite to the second metal layer 622 with respect to the second mounting layer 621. The two temperature detection wiring layers 625 are bonded to the second mounting layer 621. The two temperature detection wiring layers 625 are adjacent to each other in a direction orthogonal to the first direction z.

As shown in FIG. 12, each of the sleeves 63 is conductively bonded to one of the first wiring 61 and the second wiring 62 through the second bonding layer 69. The second bonding layer 69 is, for example, solder. The sleeves 63 are made of a conductive material such as metal. Each of the sleeves 63 has a tubular shape extending in the first direction z.

As shown in FIG. 4, the thermistor 23 is conductively bonded to the two temperature detection wiring layers 625 of the second wiring 62. The thermistor 23 is used as a temperature detection sensor for the semiconductor device A10.

As shown in FIG. 1, the first signal terminal 161, the second signal terminal 162, the third signal terminal 171, the fourth signal terminal 172, the two fifth signal terminals 18, and the sixth signal terminal 19 are each formed of a metal pin extending in the first direction z. These terminals project from a second surface 52 of the sealing resin 50, which will be described later. Further, these terminals are individually press-fitted into the sleeves 63. Hence, each of these terminals is supported by the corresponding one of the sleeves 63 and is electrically connected to one of the first wiring 61 and the second wiring 62.

As shown in FIG. 4, the first signal terminal 161 is press-fitted into the sleeve 63, among the sleeves 63, that is conductively bonded to one of the two first gate wiring layers 613 of the first wiring 61. Hence, the first signal terminal 161 is electrically connected, through the two first gate wiring layers 613, to the first gate electrode 213 of each first semiconductor element 21. The first signal terminal 161 receives a gate voltage to drive the first semiconductor elements 21.

As shown in FIG. 4, the second signal terminal 162 is press-fitted into the sleeve 63, among the sleeves 63, that is conductively bonded to one of the two second gate wiring layers 623 of the second wiring 62. Hence, the second signal terminal 162 is electrically connected, through the two second gate wiring layers 623, to the second gate electrode 223 of each second semiconductor element 22. The second signal terminal 162 receives a gate voltage to drive the second semiconductor elements 22.

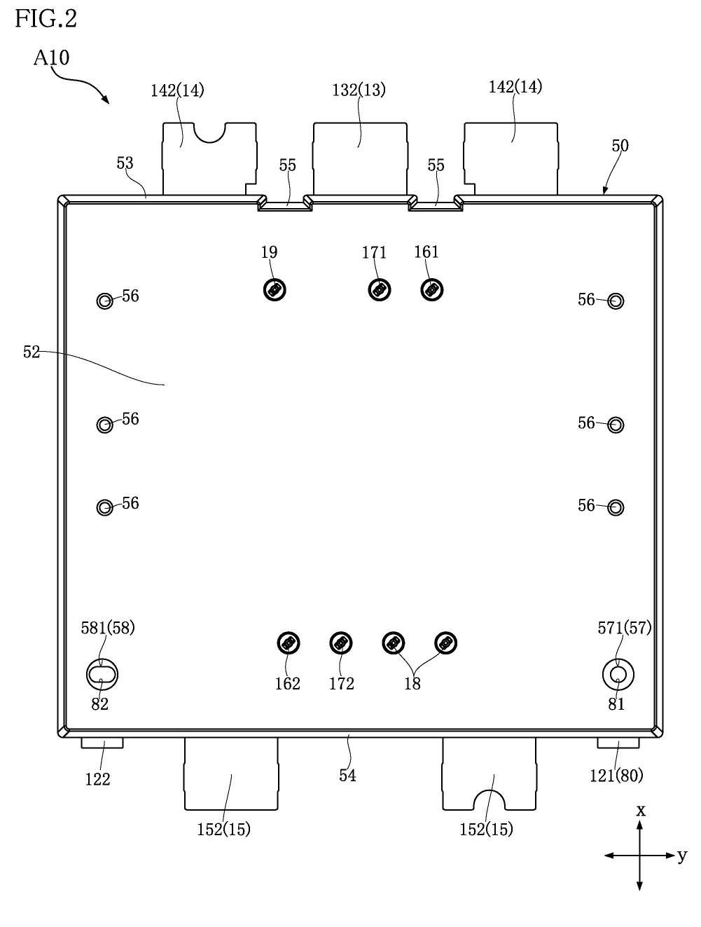

As shown in FIG. 2, the third signal terminal 171 is located next to the first signal terminal 161 in the third direction y. As shown in FIGS. 4 and 12, the third signal terminal 171 is press-fitted into the sleeve 63, among the sleeves 63, that is conductively bonded to the first detection wiring layer 614 of the first wiring 61. Hence, the third signal terminal 171 is electrically connected, through the first detection wiring layer 614, to the first detection electrode 214 of each of the first semiconductor elements 21. The third signal terminal 171 receives a voltage equivalent to that applied to the first detection electrode 214 of each first semiconductor element 21.

As shown in FIG. 2, the fourth signal terminal 172 is located next to the second signal terminal 162 in the third direction y. As shown in FIGS. 4 and 12, the fourth signal terminal 172 is press-fitted into the sleeve 63, among the sleeves 63, that is conductively bonded to the third detection wiring layer 624 of the second wiring 62. Hence, the fourth signal terminal 172 is electrically connected, through the third detection wiring layer 624, to the second detection electrode 224 of each second semiconductor element 22. The fourth signal terminal 172 receives a voltage equivalent to that applied to the second detection electrode 224 of each second semiconductor element 22.

As shown in FIG. 2, the two fifth signal terminals 18 are located on a side opposite to the fourth signal terminal 172 with respect to the second signal terminal 162 in the third direction y. The two fifth signal terminals 18 are adjacent to each other in the third direction y. As shown in FIG. 4, the two fifth signal terminals 18 are individually press-fitted into the two sleeves 63, among the sleeves 63, that are conductively bonded to the two temperature detection wiring layers 625 of the second wiring 62, respectively. Hence, the two fifth signal terminals 18 are electrically connected to the thermistor 23.

As shown in FIG. 2, the sixth signal terminal 19 is located on a side opposite to the first signal terminal 161 with respect to the third signal terminal 171 in the third direction y. As shown in FIG. 4, the sixth signal terminal 19 is press-fitted into the sleeve 63, among the sleeves 63, that is conductively bonded to the second detection wiring layer 616 of the first wiring 61. Hence, the sixth signal terminal 19 is electrically connected, through the second detection wiring layer 616, to the first conductive layer 112. The sixth signal terminal 19 receives a voltage corresponding to the DC power input to the first terminal 13 and the two second terminals 14.

As shown in FIGS. 5 and 13, the first conductive member 31 is conductively bonded to the second electrodes 212 of the respective first semiconductor elements 21 and to the second obverse surface 113A of the second conductive layer 113. Hence, the second electrode 212 of each first semiconductor element 21 is electrically connected to the second conductive layer 113. The first conductive member 31 contains copper. The first conductive member 31 is a metal clip. As shown in FIG. 5, the first conductive member 31 includes a first main portion 311, a plurality of first bonding portions 312, a plurality of first connecting portions 313, a plurality of second bonding portions 314, and a plurality of second connecting portions 315.

The first main portion 311 forms a main section of the first conductive member 31. As shown in FIG. 5, the first main portion 311 extends in the third direction y. As shown in FIG. 12, the first main portion 311 bridges between the first conductive layer 112 and the second conductive layer 113.

As shown in FIGS. 5 and 13, each of the first bonding portions 312 is conductively bonded to the second electrode 212 of one of the first semiconductor elements 21.

As shown in FIG. 5, the first connecting portions 313 are connected to the first main portion 311 and the respective first bonding portions 312. The first connecting portions 313 are spaced apart from each other in the third direction y. As shown in FIG. 13, as viewed in the third direction y, each first connecting portion 313 is inclined away from the first obverse surface 112A of the first conductive layer 112 from the corresponding first bonding portion 312 toward the first main portion 311.

As shown in FIGS. 5 and 12, the second bonding portions 314 are conductively bonded to the second obverse surface 113A of the second conductive layer 113. The second bonding portions 314 are arranged along the third direction y.

As shown in FIGS. 5 and 12, each second connecting portion 315 includes a first end in the second direction x that is connected to the first main portion 311. In addition, each second connecting portion 315 includes a second end in the second direction x that is connected to one of the second bonding portions 314. As viewed in the third direction y, each second connecting portion 315 is inclined away from the second obverse surface 113A of the second conductive layer 113 from the corresponding second bonding portion 314 toward the first main portion 311.

As shown in FIG. 13, conductive bonding layers 29 are located between the second electrodes 212 of the first semiconductor elements 21 and the first bonding portions 312, respectively. The conductive bonding layers 29 conductively bond the first bonding portions 312 to the first semiconductor elements 21, respectively. As shown in FIG. 12, conductive bonding layers 29 are located between the second obverse surface 113A of the second conductive layer 113 and the second bonding portions 314, respectively. The conductive bonding layers 29 conductively bond the second obverse surface 113A and the second bonding portions 314.

As shown in FIGS. 11 and 14, the second conductive member 32 is conductively bonded to the fourth electrodes 222 of the second semiconductor elements 22 and to the covered portions 141 of the two second terminals 14, respectively. Hence, the second electrode 212 of each second semiconductor element 22 is electrically connected to the two second terminals 14. The second conductive member 32 contains copper. The second conductive member 32 is a metal clip. As shown in FIG. 4, the second conductive member 32 includes two second main portions 321, a plurality of third bonding portions 322, a plurality of third connecting portions 323, two fourth bonding portions 324, two fourth connecting portions 325, a plurality of intermediate portions 326, and a beam portion 327.

As shown in FIG. 4, the two second main portions 321 are spaced apart from each other in the third direction y. The two second main portions 321 extend in the second direction x. As shown in FIGS. 11 and 12, the two second main portions 321 are located on a side opposite to the first conductive layer 112 and the second conductive layer 113 with respect to the first conductive member 31 in the first direction z.

As shown in FIG. 4, the intermediate portions 326 are located between the two second main portions 321 in the third direction y. The intermediate portions 326 are arranged along the third direction y. Each intermediate portion 326 extends in the second direction x.

As shown in FIGS. 4 and 14, each of the third bonding portions 322 is conductively bonded to the fourth electrode 222 of one of the second semiconductor elements 22.

As shown in FIG. 4, each third connecting portion 323 includes a first end in the third direction y that is connected to one of the third bonding portions 322. In addition, each third connecting portion 323 includes a second end in the third direction y that is connected to one of the two second main portions 321 or one of the intermediate portions 326. As viewed in the second direction x, each third connecting portion 323 is inclined away from the second obverse surface 113A of the second conductive layer 113 from the corresponding third bonding portion 322 toward the corresponding second main portion 321 or the corresponding intermediate portion 326.

As shown in FIGS. 4 and 11, the two fourth bonding portions 324 are conductively bonded to the covered portions 141 of the two second terminals 14, respectively.

As shown in FIGS. 4 and 11, each fourth connecting portion 325 includes a first end in the second direction x that is connected to the corresponding one of the two fourth bonding portions 324. In addition, each fourth connecting portion 325 includes a second end in the second direction x that is connected to the corresponding one of the two second main portions 321. As viewed in the third direction y, each fourth connecting portion 325 is inclined away from the first obverse surface 112A of the first conductive layer 112 from the corresponding fourth bonding portion 324 toward the corresponding second main portion 321.

As shown in FIG. 4, the beam portion 327 is located between the two second main portions 321 in the third direction y. The beam portion 327 extends in the third direction y. The beam portion 327 includes two ends in the third direction y that are connected to the two second main portions 321, respectively. As viewed in the first direction z, the beam portion 327 overlaps with the first conductive member 31. The beam portion 327 is connected to the intermediate portions 326 on a side on which the second semiconductor elements 22 are located in the second direction x.

As shown in FIG. 14, conductive bonding layers 29 are located between the fourth electrodes 222 of the second semiconductor elements 22 and the third bonding portions 322, respectively. The conductive bonding layers 29 conductively bond the third bonding portions 322 to the fourth electrodes 222 of the second semiconductor elements 22, respectively. As shown in FIG. 11, conductive bonding layers 29 are located between the covered portions 141 of the two second terminals 14 and the fourth bonding portions 324, respectively. The conductive bonding layers 29 conductively bond the covered portions 141 of the two second terminals 14 to the fourth bonding portions 324, respectively.

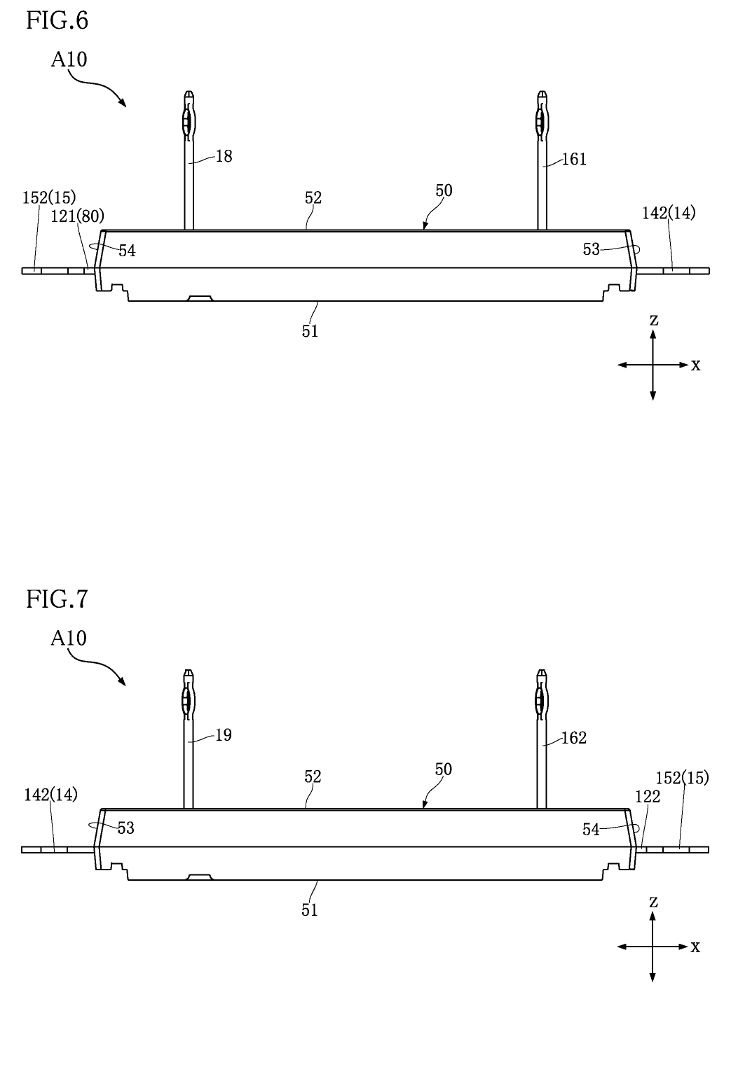

As shown in FIGS. 11, 12, 15 and 16, the sealing resin 50 covers the insulating layer 111, the first conductive layer 112, the second conductive layer 113, the first semiconductor elements 21, the second semiconductor elements 22, the first conductive member 31, and the second conductive member 32. Further, the sealing resin 50 covers a part of each of the heat dissipation layer 114, the first dummy terminal 121, the second dummy terminal 122, the first terminal 13, the third terminals 15, and the second terminals 14. The sealing resin 50 has electrical insulating properties. The sealing resin 50 is made of, for example, a material containing a black epoxy resin. As shown in FIGS. 6-9, the sealing resin 50 includes a first surface 51, a second surface 52, a third surface 53, a fourth surface 54, two first recesses 55, a plurality of second recesses 56, a first opening 57, and a second opening 58.

As shown in FIGS. 11 and 12, the first surface 51 faces away from the first obverse surface 112A of the first conductive layer 112 in the first direction z. The second surface 52 faces away from the first surface 51 in the first direction z. As shown in FIG. 10, the heat dissipation layer 114 of the base material 11 is exposed from the first surface 51.

As shown in FIGS. 2, 6 and 7, the third surface 53 and the fourth surface 54 are spaced apart from each other in the second direction x. The third surface 53 and the fourth surface 54 face away from each other in the second direction x. The exposed portion 132 of the first terminal 13 and the exposed portions 142 of the two second terminals 14 project from the third surface 53. The exposed portions 152 of the two third terminals 15 project from the fourth surface 54.

As shown in FIGS. 2, 9 and 10, the two first recesses 55 are recessed from the third surface 53 in the second direction x. The two first recesses 55 extend, in the first direction z, from the second surface 52 to the first surface 51. The two first recesses 55 are located on opposite sides with respect to the first terminal 13 in the third direction y.

As shown in FIGS. 2 and 11, the second recesses 56 are recessed from the second surface 52. The second recesses 56 are traces of ejector pins used to release the sealing resin 50 from a mold after the sealing resin 50 is formed in the mold.

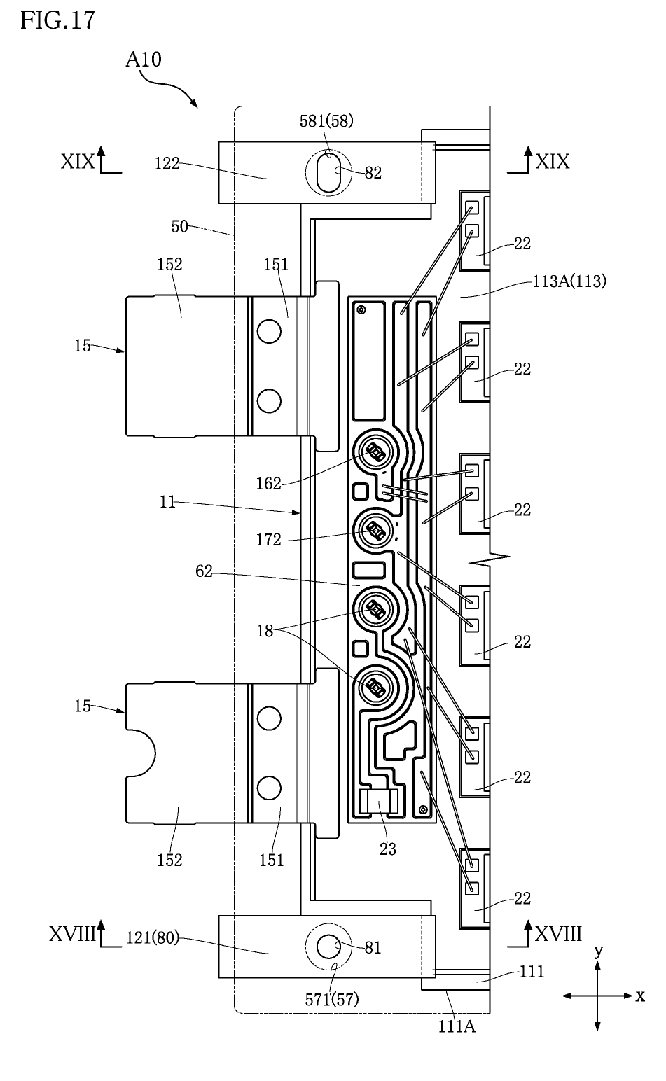

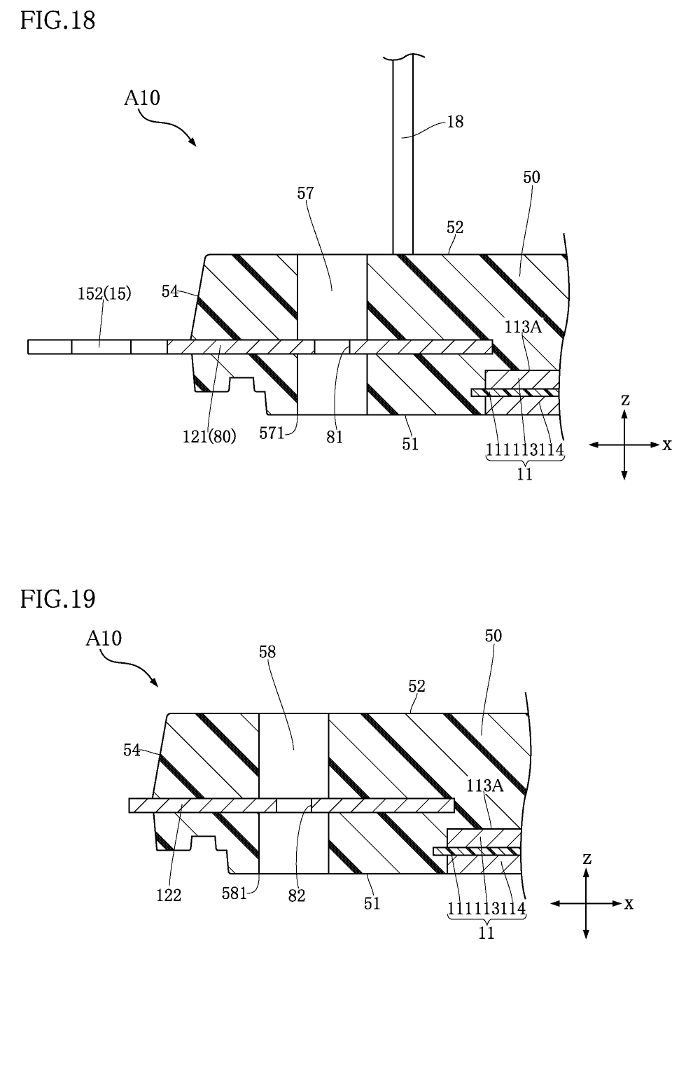

As shown in FIGS. 10 and 18, the first opening 57 is open to the first surface 51. The first opening 57 extends through the sealing resin 50 from the first surface 51 to the second surface 52. As shown in FIGS. 17 and 18, as viewed in the first direction z, the first opening 57 is spaced apart from the insulating layer 111. As shown in FIG. 10, as viewed in the first direction z, the first opening 57 is located inward of a peripheral edge 511 of the first surface 51.

As shown in FIGS. 10 and 19, the second opening 58 is open to the first surface 51. The second opening 58 extends through the sealing resin 50 from the first surface 51 to the second surface 52. As shown in FIGS. 17 and 19, as viewed in the first direction z, the second opening 58 is spaced apart from the insulating layer 111. As shown in FIG. 10, as viewed in the first direction z, the second opening 58 is located inward of the peripheral edge 511 of the first surface 51.

As shown in FIG. 3, the first dummy terminal 121 and the second dummy terminal 122 are located opposite to each other with respect to the two third terminals 15 in the third direction y. Each of the first dummy terminal 121 and the second dummy terminal 122 is spaced apart from the first conductive layer 112, the second conductive layer 113, the first terminal 13, the two second terminals 14, and the two third terminals 15. Hence, the first dummy terminal 121 and the second dummy terminal 122 are not electrically connected thereto. The first dummy terminal 121 and the second dummy terminal 122 are formed from a common lead frame for the first terminal 13, the two second terminals 14, and the two third terminals 15. Thus, a composition of each of the first dummy terminal 121 and the second dummy terminal 122 is identical to a composition of each of the first terminal 13, the two second terminals 14, and the two third terminals 15.

As shown in FIGS. 17 and 18, the first dummy terminal 121 includes a first engaging portion 81. In the present disclosure, a member including the first engaging portion 81 is referred to as a “target member 80”. In the semiconductor device A10, the target member 80 corresponds to the first dummy terminal 121. The first engaging portion 81 is exposed from the first opening 57 of the sealing resin 50. The first engaging portion 81 extends through the first dummy terminal 121 in the first direction z. As viewed in the first direction z, the first engaging portion 81 is located inward of a peripheral edge 571 of the first opening 57 and is spaced apart from the insulating layer 111. In the first direction z, the first engaging portion 81 is spaced apart from the first surface 51 and the second surface 52 of the sealing resin 50.

As shown in FIGS. 17 and 19, the second dummy terminal 122 includes a second engaging portion 82. The second engaging portion 82 is exposed from the second opening 58 of the sealing resin 50. The second engaging portion 82 extends through the second dummy terminal 122 in the first direction z. As viewed in the first direction z, the second engaging portion 82 is located inward of a peripheral edge 581 of the second opening 58 and is spaced apart from the insulating layer 111. In the first direction z, the second engaging portion 82 is spaced apart from the first surface 51 and the second surface 52 of the sealing resin 50.

As shown in FIGS. 2 and 10, a part of each of the first dummy terminal 121 and the second dummy terminal 122 projects from the fourth surface 54 of the sealing resin 50. As shown in FIG. 10, as viewed in the first direction z, a shape of the second engaging portion 82 is different from that of the first engaging portion 81. In the semiconductor device A10, the first engaging portion 81 has a circular shape, whereas the second engaging portion 82 has an oval shape elongated in the third direction y.

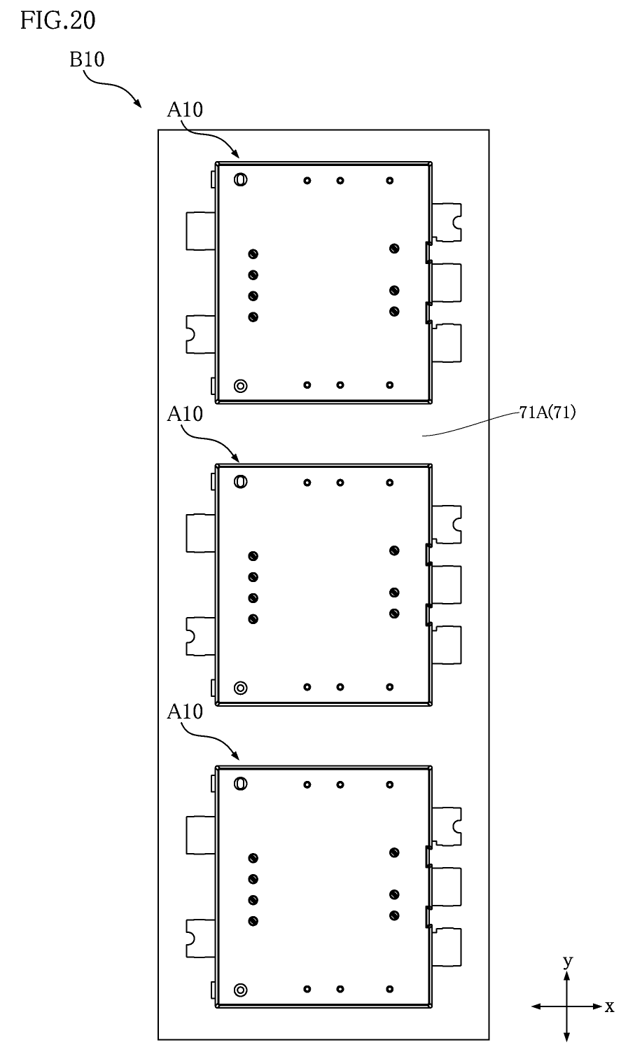

Next, a semiconductor module B10 according to the first embodiment of the present disclosure will be described with reference to FIGS. 20-22. The semiconductor module B10 includes a plurality of the semiconductor devices A10, a heat sink 71, and a bonding layer 72.

As shown in FIG. 20, the semiconductor devices A10 are mounted on the heat sink 71. The semiconductor devices A10 are arranged along the third direction y.

The heat sink 71 serves to cool the semiconductor devices A10. The heat sink 71 contains metal. The heat sink 71 is made of, for example, a material containing aluminum (Al). In the semiconductor module B10, the heat sink 71 has a plate shape. Alternatively, the heat sink 71 may be provided with fins or the like for improving heat dissipation on the first side in the first direction z.

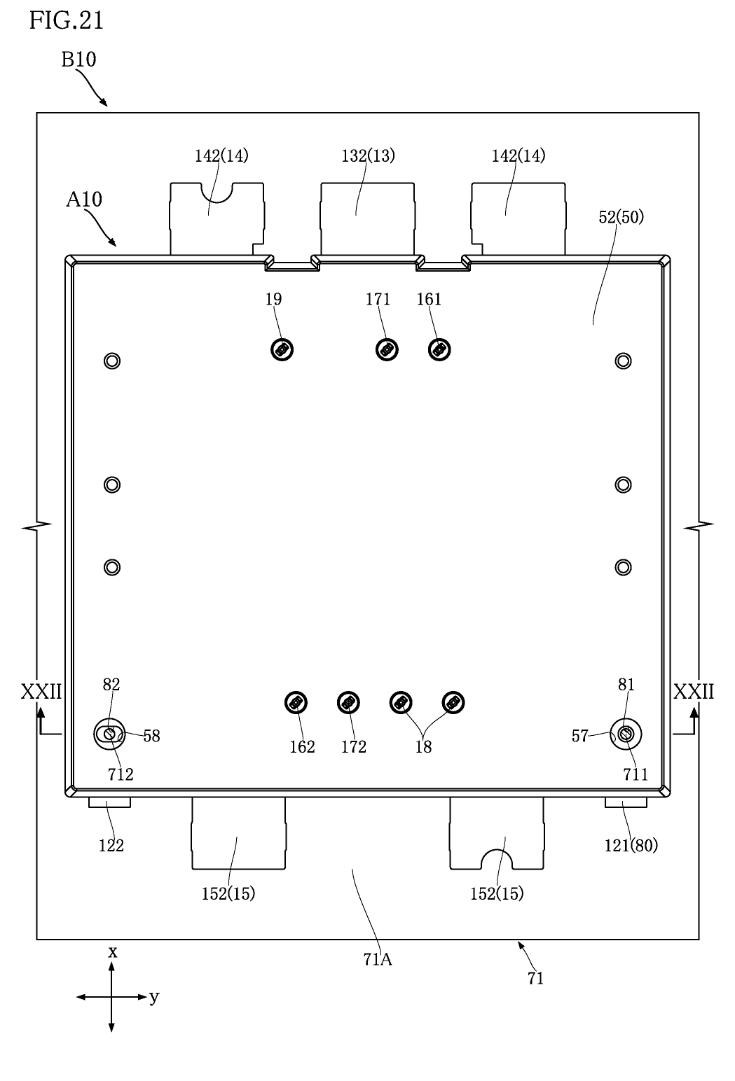

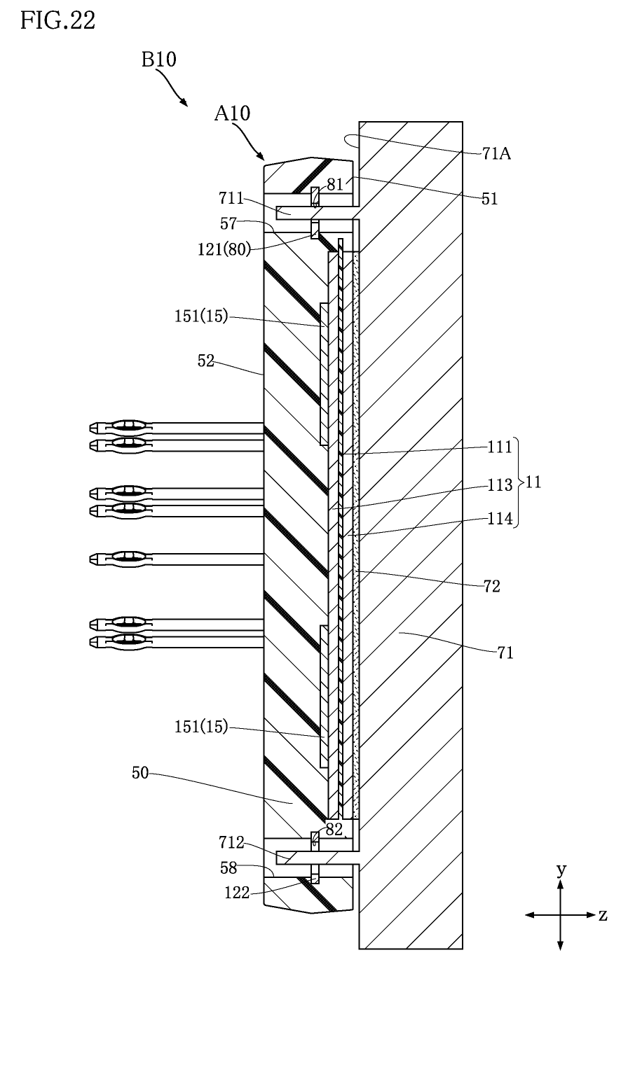

As shown in FIGS. 21 and 22, the heat sink 71 includes a mounting surface 71A, a plurality of first projections 711, and a plurality of second projections 712. The mounting surface 71A faces the first surface 51 of the sealing resin 50 of each of the semiconductor devices A10. The first projections 711 and the second projections 712 project from the mounting surface 71A. The number of the first projections 711 and the number of the second projections 712 are equal to the number of the semiconductor devices A10. The first projections 711 are individually inserted into the first openings 57 of the semiconductor devices A10, and are individually engaged with the first engaging portions 81 of the semiconductor devices A10. The second projections 712 are individually inserted into the second openings 58 of the semiconductor devices A10, and are individually engaged with the second engaging portions 82 of the semiconductor devices A10. Hence, the semiconductor devices A10 are positioned with respect to the heat sink 71 in the semiconductor module B10.

As shown in FIG. 22, the bonding layer 72 bonds the mounting surface 71A of the heat sink 71 and the heat dissipation layer 114 of each semiconductor device A10. The bonding layer 72 includes a sintered body of metal particles. The metal particles contain silver. Alternatively, the metal particles may contain copper.

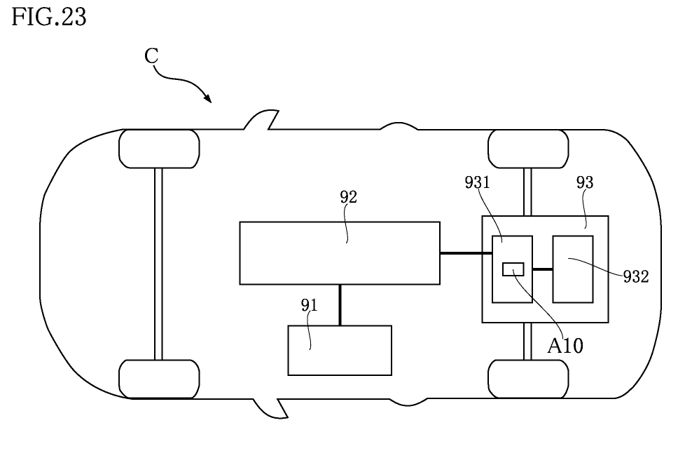

Next, a vehicle C on which the semiconductor device A10 is installed will be described with reference to FIG. 23. The vehicle C is, for example, an electric vehicle (EV).

As shown in FIG. 23, the vehicle C includes an on-board charger 91, a storage battery 92, and a drive system 93. The on-board charger 91 receives power wirelessly from an outdoor power supply facility (not shown). Alternatively, the on-board charger 91 may receive power from the power supply facility by wire. The on-board charger 91 includes a step-up DC-DC converter. The voltage of the power supplied to the on-board charger 91 is boosted by the converter and then supplied to the storage battery 92. The voltage is boosted to 600 V, for example.

The drive system 93 drives the vehicle C. The drive system 93 includes an inverter 931 and a drive source 932. The semiconductor device A10 constitutes a part of the inverter 931. Alternatively, the inverter 931 may comprise a plurality of the above-described semiconductor modules B10. The power stored in the storage battery 92 is supplied to the inverter 931. The power supplied from the storage battery 92 to the inverter 931 is DC power. In an example different from FIG. 23, the power system may additionally include a step-up DC-DC converter between the storage battery 92 and the inverter 931. The inverter 931 converts the DC power into AC power. The inverter 931 that includes the semiconductor device A10 is electrically connected to the drive source 932. The drive source 932 includes an AC motor and a transmission. The AC power converted by the inverter 931 is supplied to the drive source 932 to rotate the AC motor. The rotation of the AC motor is transmitted to the transmission. The transmission appropriately reduces the rotational speed transmitted from the AC motor and rotates the drive shaft of the vehicle C. This drives the vehicle C. Driving the vehicle C requires freely regulating the rotational speed of the AC motor based on the amount of accelerator pedal operation and other information. The semiconductor device A10 in the inverter 931 is necessary for outputting the AC power at a frequency appropriately adjusted to correspond to the required rotational speed of the AC motor.

The following describes the operation of the semiconductor device A10.

The semiconductor device A10 includes the first conductive layer 112, the first semiconductor element 21, the target member 80, and the sealing resin 50. The sealing resin 50 includes the first surface 51 facing the first direction z, and the first opening 57 open to the first surface 51. The target member 80 includes the first engaging portion 81 exposed from the first opening 57. As shown in FIGS. 21 and 22, such a configuration allows the first projection 711 of the heat sink 71 to be inserted into the first opening 57 and engaged with the first engaging portion 81 in the semiconductor module B10. Hence, the semiconductor device A10 is positioned with respect to the heat sink 71. Therefore, such a configuration may reduce positional displacement of the semiconductor device A10 with respect to the heat sink 71.

As viewed in the first direction z, the first engaging portion 81 is located inward of the peripheral edge 571 of the first opening 57 of the sealing resin 50. In the first direction z, the first engaging portion 81 is spaced apart from the first surface 51 of the sealing resin 50. The first engaging portion 81 extends through the target member 80 in the first direction z. With such a configuration, an ejector pin may be inserted into the first opening 57 during the formation of the sealing resin 50 in manufacture of the semiconductor device A10. This may prevent inflow of molten resin into the first engaging portion 81 during the formation of the sealing resin 50.

As viewed in the first direction z, the first opening 57 of the sealing resin 50 is located inward of the peripheral edge 511 of the first surface 51 of the sealing resin 50. Such a configuration may, even when the target member 80 is a conductor, suppress a reduction in dielectric breakdown voltage of the semiconductor device A10.

The semiconductor device A10 further includes the first terminal 13 electrically connected to the first conductive layer 112, and the first dummy terminal 121 spaced apart from the first conductive layer 112 and the first terminal 13. The target member 80 is the first dummy terminal 121. With such a configuration, in manufacture of the semiconductor device A10, the position of the first engaging portion 81 is determined with reference to the position of the lead frame providing the first terminal 13 and the first dummy terminal 121. Accordingly, in the semiconductor module B10, compared with a case where the position of the first engaging portion 81 is determined with reference to the base material 11, displacement between the first terminal 13 and an external connection portion may be effectively reduced.

The sealing resin 50 includes the second surface 52 facing away from the first surface 51 in the first direction z. The first opening 57 extends through the sealing resin 50 from the first surface 51 to the second surface 52. The first engaging portion 81 is spaced apart from the second surface 52 in the first direction z. Such a configuration allows ejector pins to be inserted into the first opening 57 from opposite sides in the first direction z during the formation of the sealing resin 50 in manufacture of the semiconductor device A10. Further, in the semiconductor module B10, a greater degree of freedom is achieved in setting the dimension of the first projection 711 of the heat sink 71 in the first direction z.

The semiconductor device A10 further includes the second dummy terminal 122 including the second engaging portion 82. The second engaging portion 82 extends through the second dummy terminal 122 in the first direction z. The sealing resin 50 includes the second opening 58 open to the first surface 51. As viewed in the first direction z, a shape of the second engaging portion 82 is different from a shape of the first engaging portion 81. When positioning the semiconductor device A10 with respect to the heat sink 71, such a configuration may adjust a position of the semiconductor device A10 in directions orthogonal to the first direction z, and restrict rotation of the semiconductor device A10 about an axis along the first direction z.

### Second Embodiment:

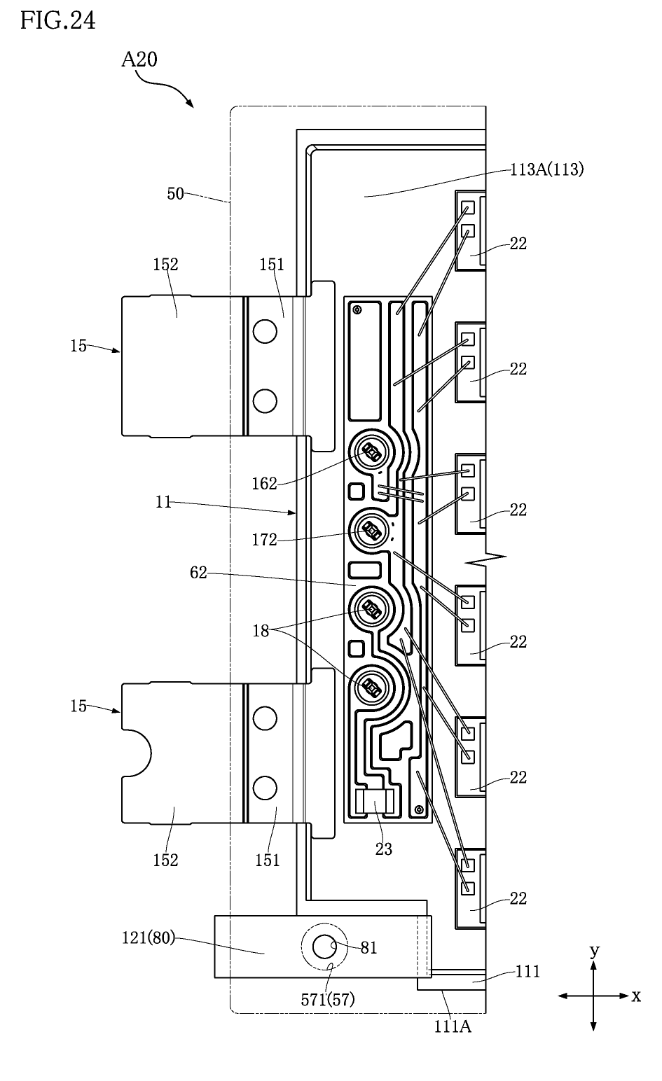

A semiconductor device A20 according to a second embodiment of the present disclosure will be described with reference to FIG. 24. Elements identical or similar to those of the semiconductor device A10 described above are marked with the same numerals in these figures, and redundant descriptions are omitted. Here, FIG. 24 corresponds to FIG. 17 showing the semiconductor device A10.

The semiconductor device A20 differs from the semiconductor device A10 in that the semiconductor device A20 does not include the second dummy terminal 122.

As shown in FIG. 24, as viewed in the first direction z, a region corresponding to the second dummy terminal 122 in the semiconductor device A10 overlaps with the second conductive layer 113 and the insulating layer 111. Since the semiconductor device A20 does not include the second dummy terminal 122, the sealing resin 50 does not include the second opening 58.

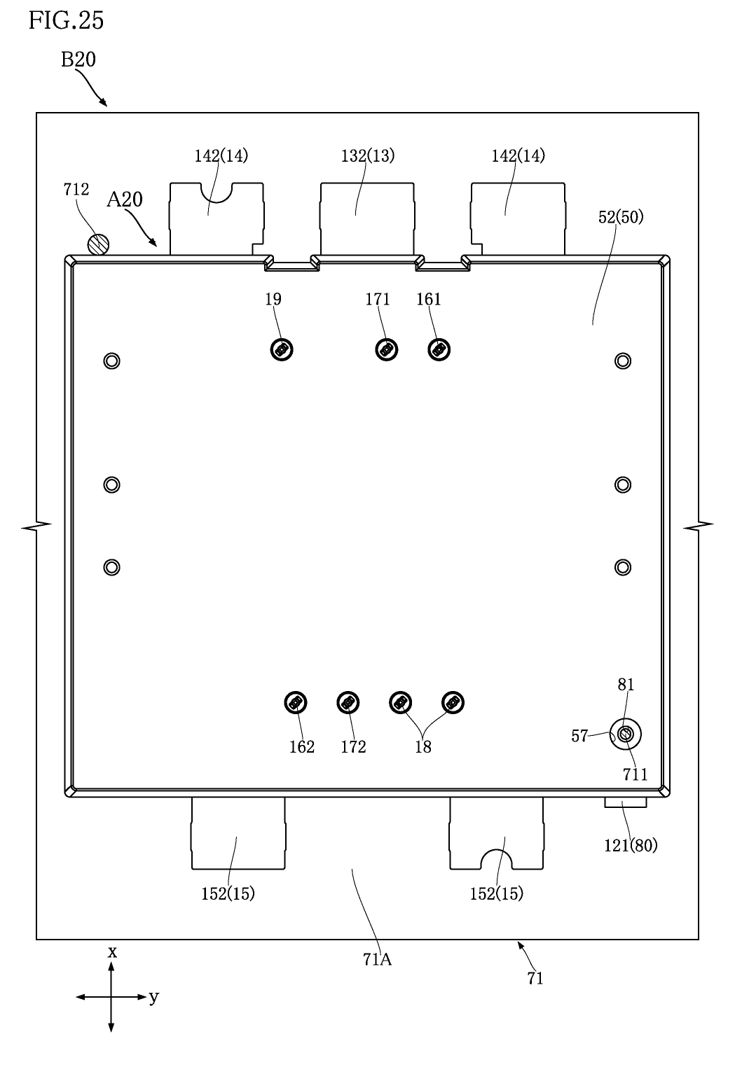

Next, a semiconductor module B20 according to the second embodiment of the present disclosure will be described with reference to FIG. 25. Elements identical or similar to those of the semiconductor module B10 described above are marked with the same numerals in these figures, and redundant descriptions are omitted. Here, FIG. 25 corresponds to FIG. 21 showing the semiconductor module B10.

The semiconductor module B20 includes a plurality of semiconductor devices A20 instead of the semiconductor devices A10. As shown in FIG. 22, as viewed in the first direction z, the second projections 712 of the heat sink 71 are located outward of the sealing resin 50 of each semiconductor device A20. Each of the second projections 712 is in contact with the sealing resin 50 of one of the semiconductor devices A20. Hence, in the semiconductor module B20, the semiconductor devices A20 are positioned with respect to the heat sink 71.

The following describes the operation of the semiconductor device A20.

The semiconductor device A20 includes the first conductive layer 112, the first semiconductor element 21, the target member 80, and the sealing resin 50. The sealing resin 50 includes the first surface 51 facing the first direction z, and the first opening 57 open to the first surface 51. The target member 80 includes the first engaging portion 81 exposed from the first opening 57. Therefore, such a configuration may reduce positional displacement of the semiconductor device A20 with respect to the heat sink 71. In addition, the semiconductor device A20 may have a configuration in common with the semiconductor device A10, thereby achieving the same effect as the semiconductor device A10.

The semiconductor device A20 does not include the second dummy terminal 122. However, even in such a configuration, as shown in FIG. 25, contact of the second projection 712 of the heat sink 71 with the sealing resin 50 may restrict rotation of the semiconductor device A20 about an axis along the first direction z.

### Third Embodiment:

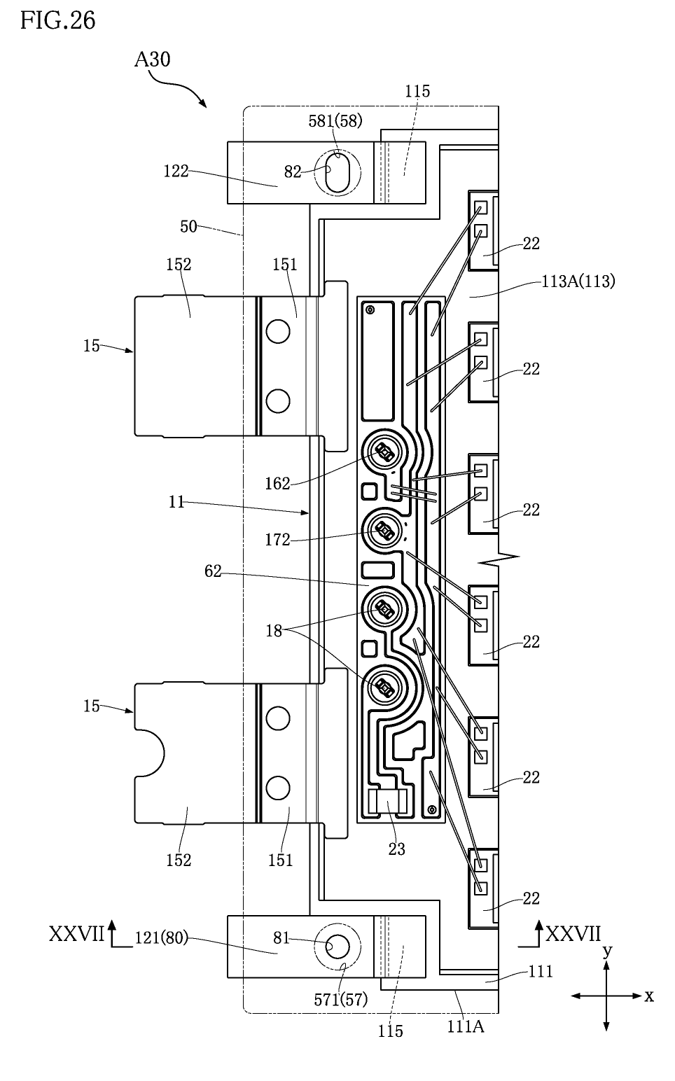

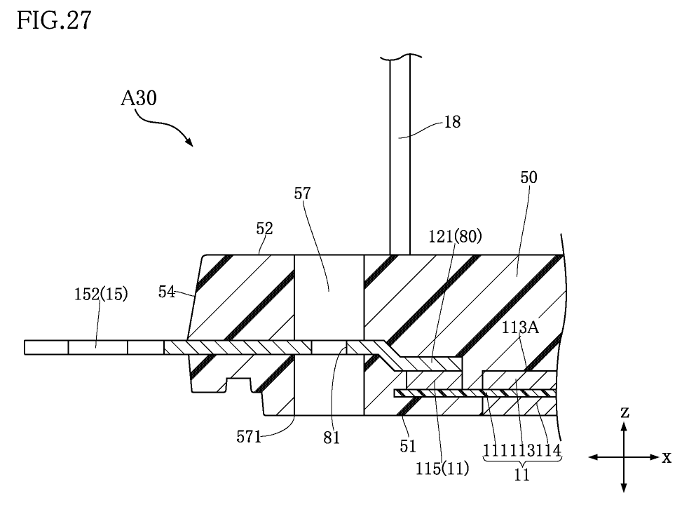

A semiconductor device A30 according to a third embodiment of the present disclosure will be described with reference to FIGS. 26 and 27. Elements identical or similar to those of the semiconductor device A10 described above are marked with the same numerals in these figures, and redundant descriptions are omitted. Here, FIG. 26 corresponds to FIG. 17 showing the semiconductor device A10.

The semiconductor device A30 differs from the semiconductor device A10 in that the semiconductor device A30 further includes two dummy layers 115.

As shown in FIG. 27, the two dummy layers 115 are located on a side opposite to the heat dissipation layer 114 with respect to the insulating layer 111 in the first direction z. The two dummy layers 115 are included in the base material 11. Each of the two dummy layers 115 is spaced apart from the first conductive layer 112 and the second conductive layer 113. Hence, each of the two dummy layers 115 is not electrically connected to the first conductive layer 112 and the second conductive layer 113. The two dummy layers 115 are bonded to the insulating layer 111. A composition of each of the two dummy layers 115 is identical to a composition of each of the first conductive layer 112 and the second conductive layer 113. As shown in FIG. 26, the two dummy layers 115 are located on opposite sides with respect to the two third terminals 15 in the third direction y. The first dummy terminal 121 and the second dummy terminal 122 are individually bonded to the two dummy layers 115.

The following describes the operation of the semiconductor device A30.

The semiconductor device A30 includes the first conductive layer 112, the first semiconductor element 21, the target member 80, and the sealing resin 50. The sealing resin 50 includes the first surface 51 facing the first direction z, and the first opening 57 open to the first surface 51. The target member 80 includes the first engaging portion 81 exposed from the first opening 57. Therefore, such a configuration may reduce positional displacement of the semiconductor device A30 with respect to the heat sink 71. In addition, the semiconductor device A30 may have a configuration in common with the semiconductor device A10, thereby achieving the same effect as the semiconductor device A10.

The semiconductor device A30 further includes the dummy layer 115. The dummy layer 115 is spaced apart from the first conductive layer 112 and is bonded to the insulating layer 111. The first dummy terminal 121 is bonded to the dummy layer 115. Such a configuration may more effectively reduce positional displacement of the base material 11 with respect to the lead frame providing the first terminal 13 and the first dummy terminal 121 in manufacture of the semiconductor device A30. Further, such a configuration may prevent the dummy terminal 121 from becoming detached from the sealing resin 50.

### Fourth Embodiment:

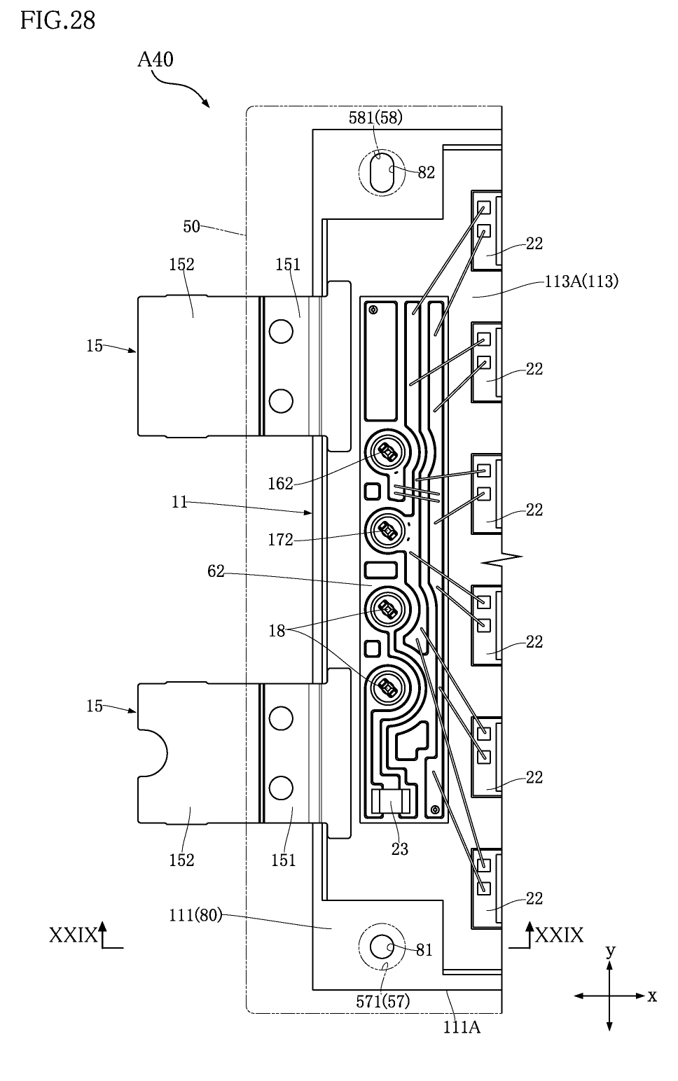

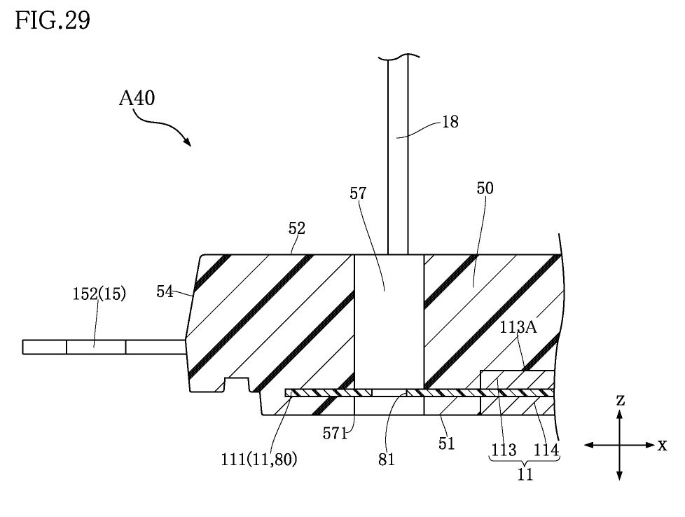

A semiconductor device A40 according to a fourth embodiment of the present disclosure will be described with reference to FIGS. 28 and 29. Elements identical or similar to those of the semiconductor device A10 described above are marked with the same numerals in these figures, and redundant descriptions are omitted. Here, FIG. 28 corresponds to FIG. 17 showing the semiconductor device A10.

The semiconductor device A40 differs from the semiconductor device A10 in that the semiconductor device A40 does not include the first dummy terminal 121 and the second dummy terminal 122, and in a configuration of the insulating layer 111.

As shown in FIGS. 28 and 29, the insulating layer 111 includes the first engaging portion 81 and the second engaging portion 82. In the semiconductor device A40, the target member 80 is the insulating layer 111. Each of the first engaging portion 81 and the second engaging portion 82 extends through the insulating layer 111 in the first direction z. As viewed in the first direction z, each of the first opening 57 and the second opening 58 of the sealing resin 50 overlaps with the insulating layer 111.

The following describes the operation of the semiconductor device A40.

The semiconductor device A40 includes the first conductive layer 112, the first semiconductor element 21, the target member 80, and the sealing resin 50. The sealing resin 50 includes the first surface 51 facing the first direction z, and the first opening 57 open to the first surface 51. The target member 80 includes the first engaging portion 81 exposed from the first opening 57. Therefore, such a configuration may reduce positional displacement of the semiconductor device A40 with respect to the heat sink 71. In addition, the semiconductor device A40 may have a configuration in common with the semiconductor device A10, thereby achieving the same effect as the semiconductor device A10.

In the semiconductor device A40, the target member 80 is the insulating layer 111. The first engaging portion 81 extends through the insulating layer 111 in the first direction z. Such a configuration does not require the first dummy terminal 121 that is exposed from the sealing resin 50 in the semiconductor device A40. This may suppress a reduction in dielectric breakdown voltage of the semiconductor device A40.

### Fifth Embodiment:

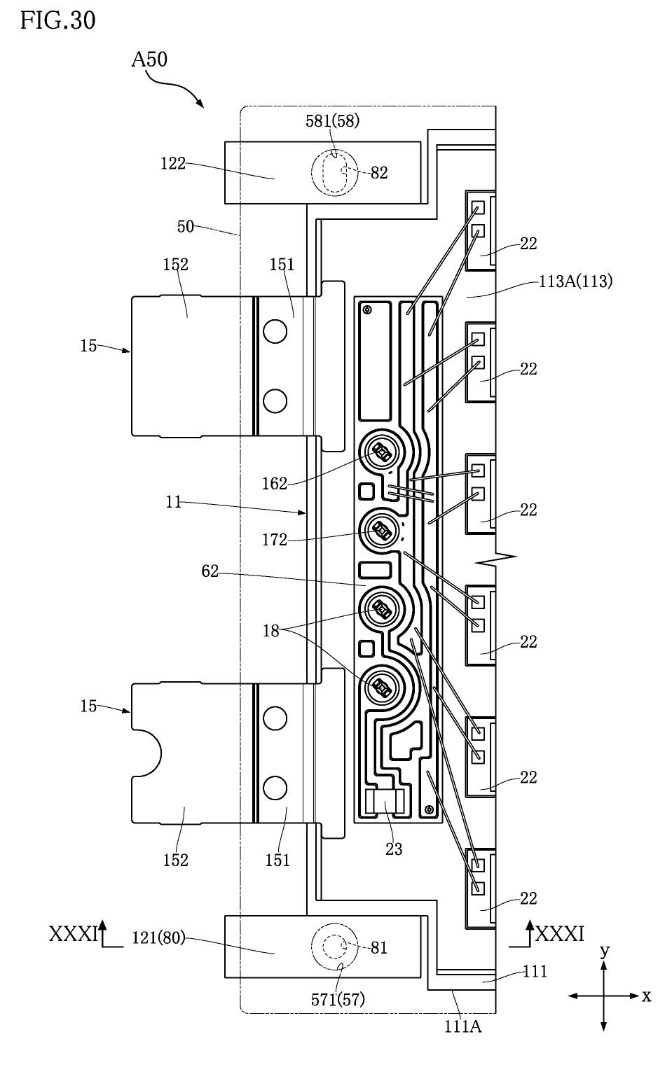

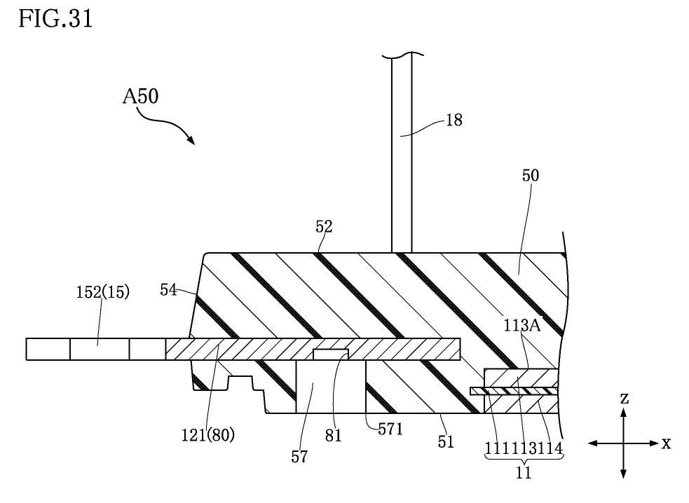

A semiconductor device A50 according to a fifth embodiment of the present disclosure will be described with reference to FIGS. 30 and 31. Elements identical or similar to those of the semiconductor device A10 described above are marked with the same numerals in these figures, and redundant descriptions are omitted. Here, FIG. 30 corresponds to FIG. 17 showing the semiconductor device A10.

The semiconductor device A50 differs from the semiconductor device A10 in configurations of the first dummy terminal 121, the second dummy terminal 122, and the sealing resin 50.

As shown in FIGS. 30 and 31, the first engaging portion 81 of the first dummy terminal 121 is a recess formed on the first dummy terminal 121, the recess extending in the first direction z away from the first surface 51 of the sealing resin 50. Similarly, the second engaging portion 82 of the second dummy terminal 122 is a recess formed on the second dummy terminal 122, the recess extending in the first direction z away from the first surface 51.

As shown in FIG. 31, the first opening 57 of the sealing resin 50 does not reach the second surface 52 of the sealing resin 50. Hence, the first opening 57 does not extend through the sealing resin 50 in the first direction z. Similarly, since the second opening 58 of the sealing resin 50 also does not reach the second surface 52, the second opening 58 does not extend through the sealing resin 50 in the first direction z.

The semiconductor device A50 may be configured to further include two dummy layers 115 as with the semiconductor device A30 described above. In this case, the first dummy terminal 121 and the second dummy terminal 122 are individually bonded to the two dummy layers 115.

The following describes the operation of the semiconductor device A50.

The semiconductor device A50 includes the first conductive layer 112, the first semiconductor element 21, the target member 80, and the sealing resin 50. The sealing resin 50 includes the first surface 51 facing the first direction z, and the first opening 57 open to the first surface 51. The target member 80 includes the first engaging portion 81 exposed from the first opening 57. Therefore, such a configuration may reduce positional displacement of the semiconductor device A50 with respect to the heat sink 71. In addition, the semiconductor device A50 may have a configuration in common with the semiconductor device A10, thereby achieving the same effect as the semiconductor device A10.

In the semiconductor device A50, the first engaging portion 81 is a recess formed on the first dummy terminal 121, the recess extending in the first direction z away from the first surface 51 of the sealing resin 50. With such a configuration, the first opening 57 of the sealing resin 50 does not extend through the sealing resin 50 in the first direction z. This may suppress a reduction in dielectric breakdown voltage of the semiconductor device A50.

### Sixth Embodiment:

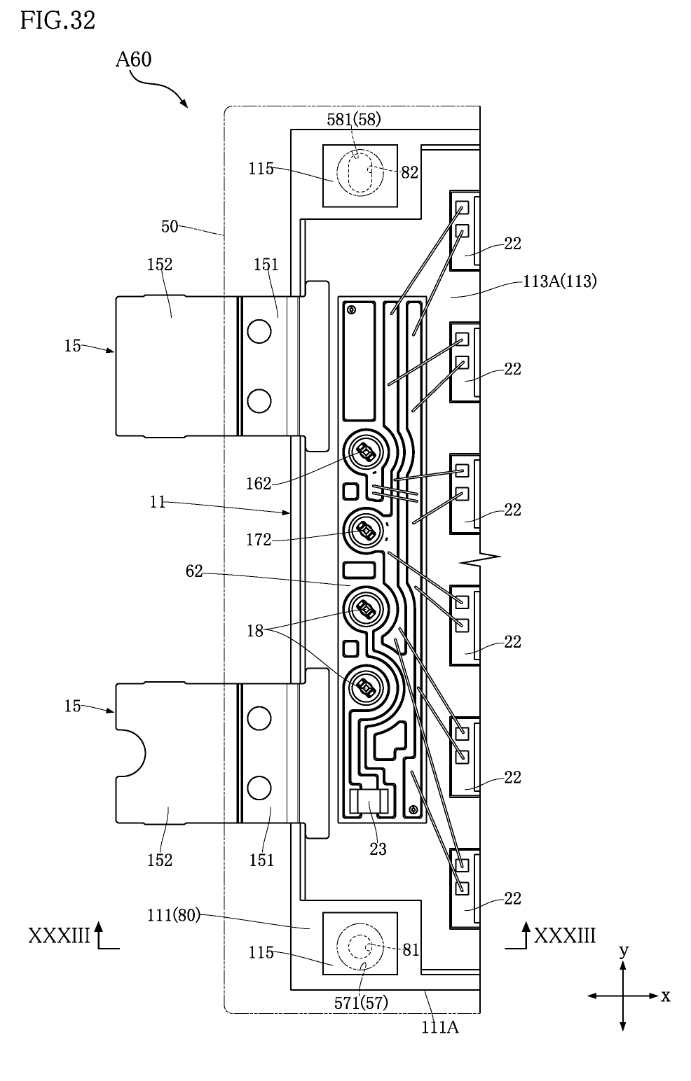

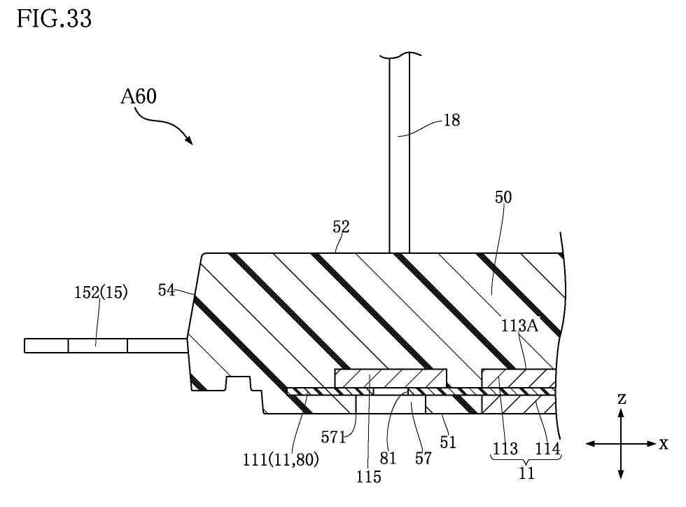

A semiconductor device A60 according to a sixth embodiment of the present disclosure will be described with reference to FIGS. 32 and 33. Elements identical or similar to those of the semiconductor device A10 described above are marked with the same numerals in these figures, and redundant descriptions are omitted. Here, FIG. 32 corresponds to FIG. 17 showing the semiconductor device A10.

The semiconductor device A60 differs from the semiconductor device A40 in that the semiconductor device A60 further includes two dummy layers 115, and in a configuration of the sealing resin 50.

As shown in FIGS. 32 and 33, one of the two dummy layers 115 closes the first engaging portion 81 at one end in the first direction z. Similarly, the other of the two dummy layers 115 closes the second engaging portion 82 at one end in the first direction z. Configurations of the two dummy layers 115 are similar to those of the two dummy layers 115 of the semiconductor device A30 described above.

As shown in FIG. 32, as viewed in the first direction z, the entirety of each of the first opening 57 and the second opening 58 of the sealing resin 50 overlaps with a corresponding one of the two dummy layers 115. Thus, as shown in FIG. 33, the first opening 57 of the sealing resin 50 does not reach the second surface 52 of the sealing resin 50. Therefore, the first opening 57 does not extend through the sealing resin 50 in the first direction z. Similarly, since the second opening 58 of the sealing resin 50 also does not reach the second surface 52, the second opening 58 does not extend through the sealing resin 50 in the first direction z.

The following describes the operation of the semiconductor device A60.

The semiconductor device A60 includes the first conductive layer 112, the first semiconductor element 21, the target member 80, and the sealing resin 50. The sealing resin 50 includes the first surface 51 facing the first direction z, and the first opening 57 open to the first surface 51. The target member 80 includes the first engaging portion 81 exposed from the first opening 57. Therefore, such a configuration may reduce positional displacement of the semiconductor device A60 with respect to the heat sink 71. In addition, the semiconductor device A60 may have a configuration in common with the semiconductor device A10, thereby achieving the same effect as the semiconductor device A10.

In the semiconductor device A60, the target member 80 is the insulating layer 111. The first engaging portion 81 extends through the insulating layer 111 in the first direction z. The semiconductor device A60 further includes the dummy layer 115. The dummy layer 115 closes the first engaging portion 81 at one end in the first direction z. With such a configuration, the first opening 57 of the sealing resin 50 does not extend through the sealing resin 50 in the first direction z. This may suppress a reduction in dielectric breakdown voltage of the semiconductor device A60.

### Seventh Embodiment:

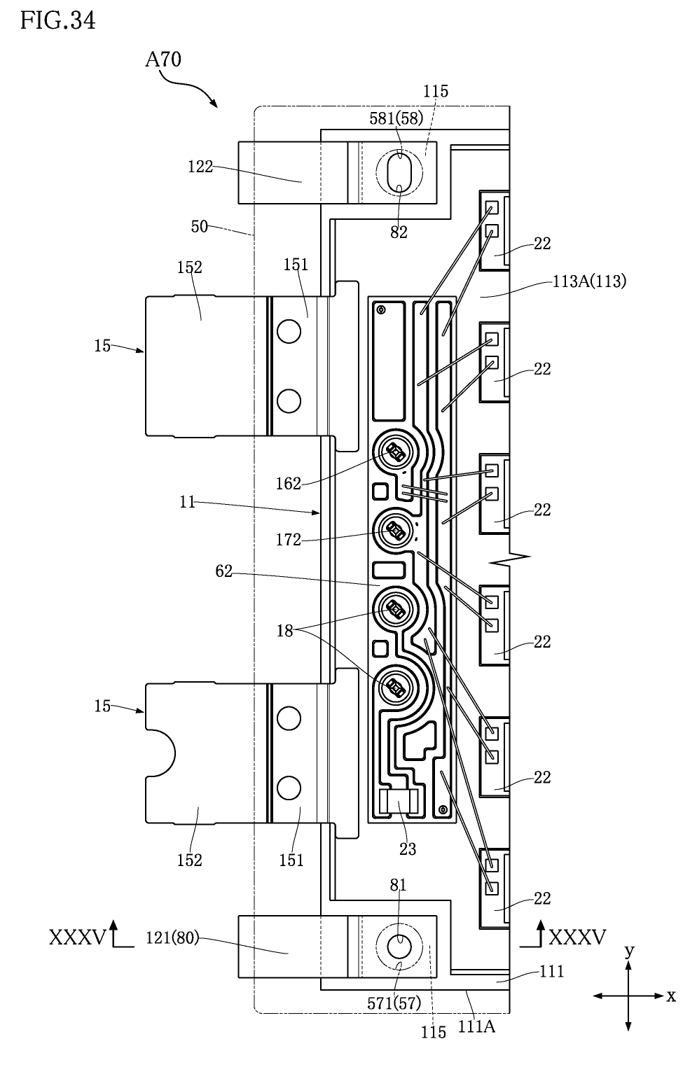

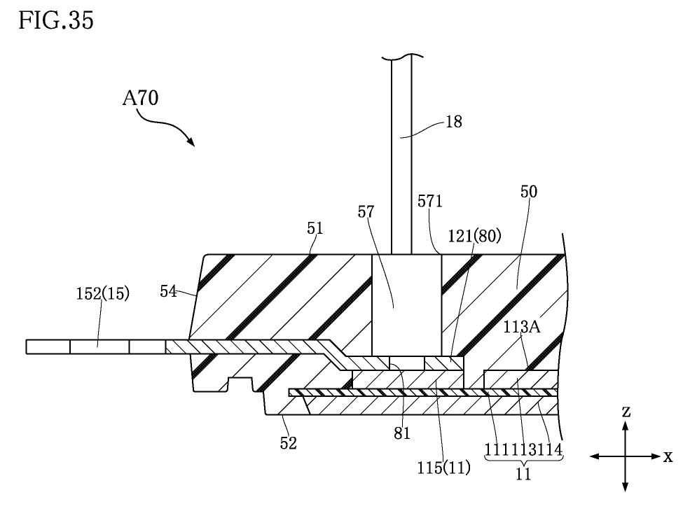

A semiconductor device A70 according to a seventh embodiment of the present disclosure will be described with reference to FIGS. 34 and 35. Elements identical or similar to those of the semiconductor device A10 described above are marked with the same numerals in these figures, and redundant descriptions are omitted. Here, FIG. 34 corresponds to FIG. 17 showing the semiconductor device A10.

The semiconductor device A70 differs from the semiconductor device A30 in configurations of the first dummy terminal 121, the second dummy terminal 122, and the sealing resin 50.

As shown in FIG. 35, in the sealing resin 50, the first surface 51 and the second surface 52 face in directions opposite to those of the semiconductor device A10 in the first direction z. Therefore, the heat dissipation layer 114 is exposed from the second surface 52.

As shown in FIG. 34, as viewed in the first direction z, the first engaging portion 81 and the second engaging portion 82 individually overlap with the two dummy layers 115. In addition, the entirety of each of the first opening 57 and the second opening 58 of the sealing resin 50 overlaps with the corresponding one of the two dummy layers 115. Thus, as shown in FIG. 35, the first opening 57 of the sealing resin 50 does not reach the second surface 52 of the sealing resin 50. This means that the first opening 57 does not extend through the sealing resin 50 in the first direction z. Similarly, since the second opening 58 of the sealing resin 50 also does not reach the second surface 52, the second opening 58 does not extend through the sealing resin 50 in the first direction z.

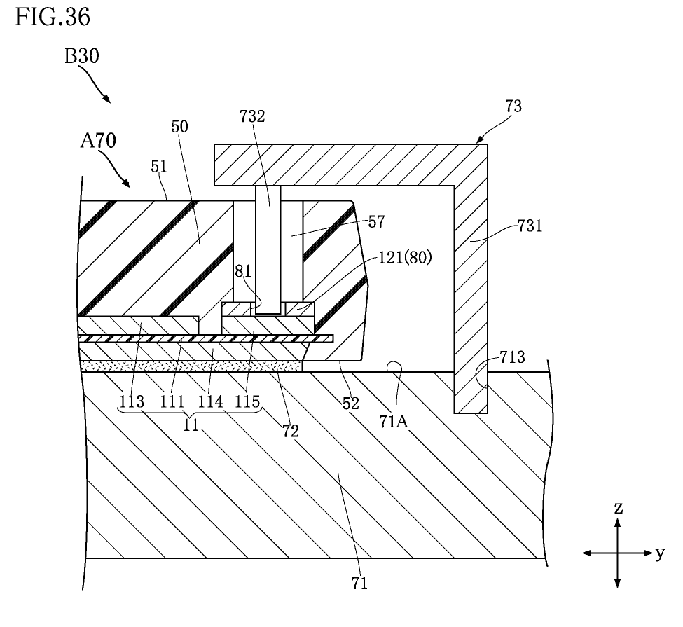

Next, a semiconductor module B30 according to the third embodiment of the present disclosure will be described with reference to FIG. 36. Elements identical or similar to those of the semiconductor module B10 described above are marked with the same numerals in these figures, and redundant descriptions are omitted.

The semiconductor module B30 includes a plurality of semiconductor devices A70 instead of the plurality of semiconductor devices A10. As shown in FIG. 36, the heat sink 71 includes a plurality of fitting portions 713 instead of the first projections 711 and the second projections 712. The fitting portions 713 are recessed from the mounting surface 71A of the heat sink 71.

As shown in FIG. 36, in the semiconductor module B30, for example, a jig 73 is used when the semiconductor devices A70 are bonded to the heat sink 71 through the bonding layer 72. The jig 73 includes a base portion 731 and pins 732. The base portion 731 is fitted into the fitting portion 713 of the heat sink 71. A pin 732 is inserted into the first opening 57 and is engaged with the first engaging portion 81 of one of the semiconductor devices A70. Similarly, a pin 732 is inserted into the second opening 58 and is engaged with the second engaging portion 82 of one of the semiconductor devices A70. Hence, in the semiconductor module B30, the semiconductor devices A70 are positioned with respect to the heat sink 71.

The following describes the operation of the semiconductor device A70.

The semiconductor device A70 includes the first conductive layer 112, the first semiconductor element 21, the target member 80, and the sealing resin 50. The sealing resin 50 includes the first surface 51 facing the first direction z, and the first opening 57 open to the first surface 51. The target member 80 includes the first engaging portion 81 exposed from the first opening 57. Therefore, such a configuration may reduce positional displacement of the semiconductor device A70 with respect to the heat sink 71. In addition, the semiconductor device A70 may have a configuration in common with the semiconductor device A10, thereby achieving the same effect as the semiconductor device A10.

In the semiconductor device A70, as viewed in the first direction z, the first engaging portion 81 and the entirety of the first opening 57 of the sealing resin 50 overlap with the dummy layer 115. With such a configuration, the first opening 57 of the sealing resin 50 does not extend through the sealing resin 50 in the first direction z. This may suppress a reduction in dielectric breakdown voltage of the semiconductor device A70. Further, as compared with the semiconductor device A10, such a configuration may increase a volume of the heat dissipation layer 114. This may improve heat dissipation.

The present disclosure is not limited to the above-described embodiments. Various modifications in design may be made freely in the specific structure of each part of the present disclosure.

The present disclosure includes embodiments described in the following clauses.

Clause 1.

A semiconductor device comprising:

a first conductive layer;

a first semiconductor element electrically connected to the first conductive layer;

a target member; and

a sealing resin covering the first conductive layer, the first semiconductor element, and a part of the target member,

wherein the sealing resin includes a first surface facing a first direction, and a first opening open to the first surface, and

the target member includes a first engaging portion exposed from the first opening.

Clause 2.

The semiconductor device according to clause 1, wherein, as viewed in the first direction, the first engaging portion is located inward of a peripheral edge of the first opening, and

the first engaging portion is spaced apart from the first surface in the first direction.

Clause 3.

The semiconductor device according to clause 2, wherein as viewed in the first direction, the first opening is located inward of a peripheral edge of the first surface.

Clause 4.

The semiconductor device according to clause 3, further comprising an insulating layer located on a side opposite to the first semiconductor element with respect to the first conductive layer in the first direction,

wherein the first conductive layer is bonded to the insulating layer,

the first semiconductor element is conductively bonded to the first conductive layer, and

at least a part of the insulating layer is covered with the sealing resin.

Clause 5.

The semiconductor device according to clause 4, wherein the first surface faces a side on which the insulating layer is located with respect to the first conductive layer in the first direction.

Clause 6.

The semiconductor device according to clause 5, further comprising a heat dissipation layer located on a side opposite to the first conductive layer with respect to the insulating layer,

wherein the heat dissipation layer is bonded to the insulating layer, and

the heat dissipation layer is exposed from the first surface.

Clause 7.

The semiconductor device according to clause 6, further comprising a first terminal electrically connected to the first conductive layer,

wherein a part of the first terminal projects from the sealing resin.

Clause 8.

The semiconductor device according to clause 7, further comprising a first dummy terminal spaced apart from the first conductive layer and the first terminal,

wherein the target member is the first dummy terminal.

Clause 9.

The semiconductor device according to clause 8, wherein, as viewed in the first direction, the first engaging portion is spaced apart from the insulating layer.

Clause 10.

The semiconductor device according to clause 9, wherein the first engaging portion extends through the first dummy terminal in the first direction.

Clause 11.

The semiconductor device according to clause 9, wherein the first engaging portion is a recess formed on the first dummy terminal, the recess extending in the first direction away from the first surface.

Clause 12.

The semiconductor device according to clause 10 or 11, further comprising a dummy layer located on a side opposite to the heat dissipation layer with respect to the insulating layer and spaced apart from the first conductive layer,

wherein a composition of the dummy layer is identical to a composition of the first conductive layer,

the dummy layer is bonded to the insulating layer, and

the first dummy terminal is bonded to the dummy layer.

Clause 13.

The semiconductor device according to clause 6, wherein the target member is the insulating layer, and

the first engaging portion extends through the insulating layer in the first direction.

Clause 14.

The semiconductor device according to clause 9, wherein the sealing resin includes a second surface facing away from the first surface in the first direction,

the first opening extends through the sealing resin from the first surface to the second surface, and

the first engaging portion is spaced apart from the second surface in the first direction.

Clause 15.

The semiconductor device according to clause 14, further comprising a second dummy terminal spaced apart from the first conductive layer and the first terminal and exposed from the sealing resin,

wherein the sealing resin includes a second opening spaced apart from the first opening and open to the first surface,

the second dummy terminal includes a second engaging portion exposed from the second opening, and

as viewed in the first direction, the second engaging portion is located inward of a peripheral edge of the second opening.

Clause 16.

The semiconductor device according to clause 15, wherein the second opening extends through the sealing resin from the first surface to the second surface,

the second engaging portion extends through the second dummy terminal in the first direction,

the second engaging portion is spaced apart from the first surface and the second surface in the first direction, and

as viewed in the first direction, a shape of the second engaging portion is different from a shape of the first engaging portion.

Clause 17.

The semiconductor device according to clause 16, further comprising:

a second conductive layer located on a side opposite to the heat dissipation layer with respect to the insulating layer and bonded to the insulating layer;

a second semiconductor element conductively bonded to the second conductive layer and electrically connected to the first semiconductor element; and

a third terminal electrically connected to the second conductive layer,

wherein the sealing resin includes a third surface and a fourth surface facing away from each other in a second direction orthogonal to the first direction,

a part of the first terminal projects from the third surface,

a part of the third terminal projects from the fourth surface, and

the first dummy terminal and the second dummy terminal are exposed from the fourth surface.

Clause 18.

A semiconductor module comprising:

the semiconductor device according to clause 9; and

a heat sink including a mounting surface facing the first surface,

wherein the heat dissipation layer is bonded to the mounting surface,

the heat sink includes a first projection projecting from the mounting surface, and

the first projection is inserted into the first opening and engaged with the first engaging portion.

Clause 19.

The semiconductor module according to clause 18, further comprising a bonding layer bonding the mounting surface and the heat dissipation layer,

wherein the bonding layer includes a sintered body of metal particles.

Clause 20.

A vehicle comprising:

a drive source; and

the semiconductor device according to clause 1,

wherein the semiconductor device is electrically connected to the drive source.

Clause 21.

The semiconductor device according to clause 8, wherein a composition of the first dummy terminal is identical to a composition of the first terminal.

Clause 22.

The semiconductor device according to clause 21, wherein a part of the first dummy terminal projects from the sealing resin in a second direction orthogonal to the first direction.

Clause 23.

The semiconductor device according to clause 4, wherein the first surface faces a side on which the first semiconductor element is located with respect to the first conductive layer in the first direction.

Clause 24.

The semiconductor device according to clause 23, further comprising:

a first terminal electrically connected to the first conductive layer; and

a first dummy terminal spaced apart from the first terminal,

wherein the target member is the first dummy terminal,

a part of the first terminal projects from the sealing resin, and

as viewed in the first direction, the first engaging portion overlaps with the insulating layer.

Clause 25.

The semiconductor device according to clause 13, further comprising a dummy layer located on a side opposite to the heat dissipation layer with respect to the insulating layer and spaced apart from the first conductive layer,

wherein a composition of the dummy layer is identical to a composition of the first conductive layer,

the dummy layer is bonded to the insulating layer, and

the dummy layer closes the first engaging portion at one end in the first direction.

Clause 26.

The semiconductor device according to clause 17, wherein a part of each of the first dummy terminal and the second dummy terminal projects from the fourth surface.

Clause 27.

The semiconductor device according to clause 26, wherein the first dummy terminal and the second dummy terminal are located opposite to each other with respect to the third terminal in a third direction orthogonal to the first direction and the second direction.

Clause 28.

The semiconductor device according to clause 17, further comprising:

a first signal terminal electrically connected to the first semiconductor element; and

a second signal terminal electrically connected to the second semiconductor element,

wherein a part of each of the first signal terminal and the second signal terminal projects from the second surface.

Clause 29.

The semiconductor module according to clause 19, wherein the metal particles include silver.

1. A semiconductor device comprising:
a first conductive layer;
a first semiconductor element electrically connected to the first conductive layer;
a target member; and
a sealing resin covering the first conductive layer, the first semiconductor element, and a part of the target member,
wherein the sealing resin includes a first surface facing a first direction, and a first opening open to the first surface; and
the target member includes a first engaging portion exposed from the first opening.

2. The semiconductor device according to claim 1, wherein, as viewed in the first direction, the first engaging portion is located inward of a peripheral edge of the first opening; and
the first engaging portion is spaced apart from the first surface in the first direction.

3. The semiconductor device according to claim 2, wherein, as viewed in the first direction, the first opening is located inward of a peripheral edge of the first surface.

4. The semiconductor device according to claim 3, further comprising an insulating layer located on a side opposite to the first semiconductor element with respect to the first conductive layer in the first direction,
wherein the first conductive layer is bonded to the insulating layer;
the first semiconductor element is conductively bonded to the first conductive layer; and
at least a part of the insulating layer is covered with the sealing resin.

5. The semiconductor device according to claim 4, wherein the first surface faces a side on which the insulating layer is located with respect to the first conductive layer in the first direction.

6. The semiconductor device according to claim 5, further comprising a heat dissipation layer located on a side opposite to the first conductive layer with respect to the insulating layer,
wherein the heat dissipation layer is bonded to the insulating layer; and
the heat dissipation layer is exposed from the first surface.

7. The semiconductor device according to claim 6, further comprising a first terminal electrically connected to the first conductive layer,
wherein a part of the first terminal projects from the sealing resin.

8. The semiconductor device according to claim 7, wherein the target member includes a first dummy terminal; and
the first dummy terminal is spaced apart from the first conductive layer and the first terminal.

9. The semiconductor device according to claim 8, wherein, as viewed in the first direction, the first engaging portion is spaced apart from the insulating layer.

10. The semiconductor device according to claim 9, wherein the first engaging portion extends through the first dummy terminal in the first direction.

11. The semiconductor device according to claim 9, wherein the first engaging portion is a recess formed on the first dummy terminal, the recess extending in the first direction away from the first surface.

12. The semiconductor device according to claim 10, further comprising a dummy layer located on a side opposite to the heat dissipation layer with respect to the insulating layer and spaced apart from the first conductive layer,
wherein a composition of the dummy layer is identical to a composition of the first conductive layer,
the dummy layer is bonded to the insulating layer, and
the first dummy terminal is bonded to the dummy layer.

13. The semiconductor device according to claim 6, wherein the target member is the insulating layer, and
the first engaging portion extends through the insulating layer in the first direction.

14. The semiconductor device according to claim 9, wherein the sealing resin includes a second surface facing away from the first surface in the first direction,
the first opening extends through the sealing resin from the first surface to the second surface, and
the first engaging portion is spaced apart from the second surface in the first direction.

15. The semiconductor device according to claim 14, further comprising a second dummy terminal spaced apart from the first conductive layer and the first terminal and exposed from the sealing resin,
wherein the sealing resin includes a second opening spaced apart from the first opening and open to the first surface,
the second dummy terminal includes a second engaging portion exposed from the second opening, and
as viewed in the first direction, the second engaging portion is located inward of a peripheral edge of the second opening.

16. The semiconductor device according to claim 15, wherein the second opening extends through the sealing resin from the first surface to the second surface,
the second engaging portion extends through the second dummy terminal in the first direction;
the second engaging portion is spaced apart from the first surface and the second surface in the first direction, and
as viewed in the first direction, a shape of the second engaging portion is different from a shape of the first engaging portion.

17. The semiconductor device according to claim 16, further comprising:
a second conductive layer located on a side opposite to the heat dissipation layer with respect to the insulating layer and bonded to the insulating layer;
a second semiconductor element conductively bonded to the second conductive layer and electrically connected to the first semiconductor element; and
a third terminal electrically connected to the second conductive layer,
wherein the sealing resin includes a third surface and a fourth surface facing away from each other in a second direction orthogonal to the first direction,
a part of the first terminal projects from the third surface,
a part of the third terminal projects from the fourth surface, and
the first dummy terminal and the second dummy terminal are exposed from the fourth surface.

18. A semiconductor module comprising:
the semiconductor device according to claim 9; and
a heat sink including a mounting surface facing the first surface,
wherein the heat dissipation layer is bonded to the mounting surface;
the heat sink includes a first projection projecting from the mounting surface, and
the first projection is inserted into the first opening and engaged with the first engaging portion.

19. The semiconductor module according to claim 18, further comprising a bonding layer bonding the mounting surface and the heat dissipation layer,
wherein the bonding layer includes a sintered body of metal particles.

20. A vehicle comprising:
a drive source; and
the semiconductor device according to claim 1,
wherein the semiconductor device is electrically connected to the drive source.
